(19) United States
(12) Patent Application Publication
(10) Pub. No.: US 2026/0344273 A1
(43) Pub. Date: Oct. 29, 2026

(54) DISPLAY PANEL AND DISPLAY DEVICE

(71) Applicant: Hubei Yangtze Industrial Innovation Center Of Advanced Display Co., Ltd., Wuhan (CN)

(72) Inventors: Shucheng GE, Wuhan (CN); Tianle CHENG, Wuhan (CN); Yu CAI, Wuhan (CN)

(73) Assignee: Hubei Yangtze Industrial Innovation Center Of Advanced Display Co., Ltd., Wuhan (CN)

(21) Appl. No.: 19/705,950

(22) Filed: Jun. 12, 2026

(30) Foreign Application Priority Data
Dec. 31, 2025 (CN) 202512059202.4

(51) Int. Cl. H10K 59/80; H10K 59/122; H10K 59/35; H10K 59/38; H10K 59/40; H10K 102/00

(52) U.S. Cl. CPC H10K 59/8792; H10K 59/122; H10K 59/353; H10K 59/38; H10K 59/40; H10K 2102/351

(57) ABSTRACT

Provided are a display panel and a display device, configured to make the display panel have a privacy mode and a sharing mode, and simplify a forming processes of the display panel while ensuring the privacy display effect and the sharing display effect of the display panel. In the display panel, a light emitting unit layer includes first-color light emitting units including at least a first light emitting unit and a second light emitting unit; color filters include first-color filters and second-color filters that have different colors, and the first-color filters at least partially overlap with the first-color light emitting units in a direction perpendicular to a plane of the substrate; and a light shielding layer includes a first light shielding portion, a first opening and a second opening, and the first light shielding portion includes a first-color filter and a second-color filter that are stacked.

### CROSS-REFERENCE TO RELATED APPLICATIONS

The present application claims priority to Chinese Patent Application No. 202512059202.4, filed on Dec. 31, 2025, the content of which is incorporated herein by reference in its entirety.

### TECHNICAL FIELD

The present disclosure relates to the field of display technologies, and in particular, to a display panel and a display device.

### BACKGROUND

With the continuous development of display technologies, consumers have an increasing requirement for display screens. At present, various types of displays, including liquid crystal display screens and organic light emitting display screens, are emerging one after another and have developed rapidly. On this basis, display technologies such as 3D display, touch display technology, curved display, ultra-high-resolution display, and privacy display are continuously emerging.

At present, performance improvement of a privacy display screen using an active light emitting display panel such as an organic light emitting diode (OLED) has attracted great attention from researchers.

### SUMMARY

Embodiments of the present disclosure provide a display panel and a display device, configured to make the display panel have a privacy mode and a sharing mode, and simplify a structure of the display panel having a privacy function, and a forming processes of the display panel can be simplified.

In a first aspect, an embodiment of the present disclosure provides a display panel, including: a substrate; a light emitting unit layer located on a side of the substrate, the light emitting unit layer including first-color light emitting units, and the first-color light emitting units including at least a first light emitting unit and a second light emitting unit; color filters including first-color filters and second-color filters, a color of the first-color filters being different from a color of the second-color filters, the first-color filters being located on a light-exiting side of the first-color light emitting units, and in a direction perpendicular to a plane of the substrate, the first-color filters at least partially overlapping with the first-color light emitting units; and a light shielding layer located on a light-exiting side of the light emitting unit layer. The light shielding layer includes a first light shielding portion, a first opening and a second opening, the first light shielding portion surrounds the first opening; and along the direction perpendicular to the plane of the substrate, the first light shielding portion at least partially does not overlap with the first light emitting unit, the first opening at least partially overlaps with the first light emitting unit, and the second opening at least partially overlaps with the second light emitting unit. The first light shielding portion includes a first-color filter and a second-color filter that are stacked.

In a second aspect, an embodiment of the present disclosure provides a display device including the display panel described above.

### BRIEF DESCRIPTION OF DRAWINGS

In order to better illustrate the technical solutions of the present disclosure, the following briefly describes the drawings that need to be used in the embodiments. Apparently, the drawings described below are merely some embodiments of the present disclosure, and for a person of ordinary skill in the art, other drawings may be obtained based on these drawings.

FIG. 1 is a sectional schematic diagram of a display panel according to an embodiment of the present disclosure;

FIG. 2a is a top-view schematic diagram of a display panel according to an embodiment of the present disclosure;

FIG. 2b is a sectional schematic diagram of FIG. 2a along CC’;

FIG. 3 is a sectional schematic diagram of another display panel according to an embodiment of the present disclosure;

FIG. 4 is a sectional schematic diagram of another display panel according to an embodiment of the present disclosure;

FIG. 5 is a sectional schematic diagram of another display panel according to an embodiment of the present disclosure;

FIG. 6 is a sectional schematic diagram of another display panel according to an embodiment of the present disclosure;

FIG. 7 is a top-view schematic diagram of a display panel according to an embodiment of the present disclosure;

FIG. 8 is a sectional schematic diagram of FIG. 7 along BB’;

FIG. 9 is a top-view schematic diagram of another display panel according to an embodiment of the present disclosure;

FIG. 10 is a top-view schematic diagram of another display panel according to an embodiment of the present disclosure;

FIG. 11 is a sectional schematic diagram of another display panel according to an embodiment of the present disclosure;

FIG. 12 is a sectional schematic diagram of another display panel according to an embodiment of the present disclosure;

FIG. 13 is a sectional schematic diagram of another display panel according to an embodiment of the present disclosure;

FIG. 14 is a sectional schematic diagram of another display panel according to an embodiment of the present disclosure;

FIG. 15 is a sectional schematic diagram of another display panel according to an embodiment of the present disclosure;

FIG. 16 is a sectional schematic diagram of another display panel according to an embodiment of the present disclosure;

FIG. 17 is a sectional schematic diagram of another display panel according to an embodiment of the present disclosure;

FIG. 18 is a top-view schematic diagram of another display panel according to an embodiment of the present disclosure;

FIG. 19 is a top-view schematic diagram of another display panel according to an embodiment of the present disclosure;

FIG. 20 is a top-view schematic diagram of another display panel according to an embodiment of the present disclosure;

FIG. 21 is a spectral schematic diagram of a red color filter, a blue color filter and a green color filter according to an embodiment of the present disclosure; and

FIG. 22 is a schematic diagram of a display device according to an embodiment of the present disclosure.

### DESCRIPTION OF EMBODIMENTS

In order to better illustrate the technical solutions of the present disclosure, embodiments of the present disclosure will be described in detail below with reference to the drawings.

It should be clear that the described embodiments are merely some of the embodiments of the present disclosure rather than all of the embodiments. Based on the embodiments of the present disclosure, all other embodiments obtained by those of ordinary skill in the art shall fall within the protection scope of the present disclosure.

Terms used in the embodiments of the present disclosure are merely for the purpose of describing specific embodiments, but not intended to limit the present disclosure. Singular forms of “a/an”, “said” and “the” used in the embodiments of the present disclosure and the appended claims are also intended to include plural forms, unless the context clearly indicates otherwise.

It should be understood that the term “and/or” used herein is merely an association relationship describing associated objects, indicating that there may be three relationships, for example, A and/or B, and may indicate: only A, both A and B, and only B. In addition, the character “/” herein generally indicates that the related objects before and after the character present an “or” relationship.

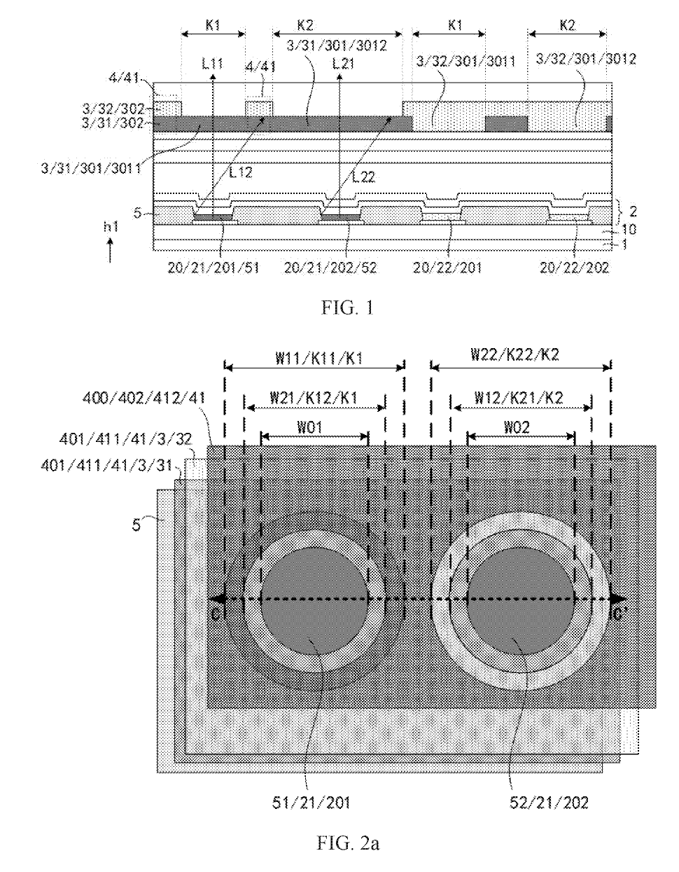

An embodiment of the present disclosure provides a display panel. As shown in FIG. 1, FIG. 1 is a sectional schematic diagram of a display panel according to an embodiment of the present disclosure. The display panel includes a substrate 1, a light emitting unit layer 2, color filters 3 and a light shielding layer 4. The light emitting unit layer 2 is located on one side of the substrate 1. The light emitting unit layer 2 includes light emitting units 20.

As shown in FIG. 1, the light emitting units 20 at least include a first-color light emitting unit 21. The first-color light emitting unit 21 refers to that the light-exiting color of the light emitting unit 20 is a first color.

In the embodiments of the present disclosure, the first-color light emitting units 21 at least include a first light emitting unit 201 and a second light emitting unit 202. The first light emitting unit 201 and the second light emitting unit 202 in the first-color light emitting units 21 have a same light-exiting color, for example, both are the first color.

Exemplarily, the operation mode of the display panel includes a privacy mode and a sharing mode. A viewing angle of the display panel in the sharing mode is greater than a viewing angle of the display panel in the privacy mode. For example, the maximum viewing angle of the display panel in the privacy mode is 45° (the viewing angle range is 0 to 45°), that is, a viewer viewing the display panel at a viewing angle greater than 45° cannot clearly see or cannot see a display image. The maximum viewing angle of the display panel in the sharing mode is at least 60° (the corresponding viewing angle range is 0 to 60°), and some display panels require the maximum viewing angle in the sharing mode be 65° (the viewing angle range is 0 to 65°). It is understandable that the maximum viewing angle in the sharing mode may be adjusted according to user requirements.

When the display panel is in operation, at least the first light emitting unit 201 emits light in the privacy mode, and at least the second light emitting unit 202 emits light in the sharing mode. That is, the first light emitting unit 201 may serve as a privacy pixel, and the second light emitting unit 202 may serve as a sharing pixel.

In some optional implementations, in the privacy mode, only the first light emitting unit 201 may be lit, and the second light emitting unit 202 may not be lit. In the sharing mode, only the second light emitting unit 202 may be lit, and the first light emitting unit 201 may not be lit.

Exemplarily, as shown in FIG. 1, the display panel further includes color filters (CF) 3. The color filters 3 include a first-color filter 31 and a second-color filter 32, and the first-color filter 31 and the second-color filter 32 have different colors. For example, the first-color filter 31 has relatively high transmittance for light of the first color and has relatively low transmittance for light of the second color. The second-color filter 32 has relatively high transmittance for light of the second color and has relatively low transmittance for light of the first color. That is, light transmission wavebands of the first-color filter 31 and the second-color filter 32 are staggered from each other. In other words, the first-color filter 31 can transmit light having a wavelength within a first waveband range and block light in other waveband. The second-color filter 32 can transmit light having a wavelength within a second waveband range and block light in other waveband. The first waveband range is different from the second waveband range.

As shown in FIG. 1, first-color filters 31 are located on a light-exiting side of the first-color light emitting unit 21. Along a direction h1 perpendicular to a plane of the substrate 1, the first-color filter 31 at least partially overlaps with the first-color light emitting unit 21. The emitted light of the first-color light emitting unit 21 may be emitted through the first-color filter 31, so as to improve the accuracy of the light-exiting color of the first-color light emitting unit 21. In addition, the color filter 3 may also absorb ambient light incident to the display panel, which is beneficial to reducing the reflectivity of the display panel. Further, based on such a configuration, it is equivalent that the color filter 3 is reused as a polarizer, so that no additional polarizer needs to be additionally arranged on the light-exiting side of the display panel, which is beneficial to reducing the thickness of the display panel.

In the embodiments of the present disclosure, a light transmission waveband of the color filter 3 at least partially overlaps with a light-exiting waveband of the light emitting unit 20 overlapping therewith. For example, the light transmission waveband of the first-color filter 31 at least partially overlaps with a light-exiting waveband of the first-color light emitting unit 21 overlapping therewith.

Exemplarily, as shown in FIG. 1, the display panel further includes a second-color light emitting unit 22, and the light-exiting color of the second-color light emitting unit 22 is different from that of the first-color light emitting unit 21. For example, the light-exiting color of the second-color light emitting unit 22 is the second color, and the second color is different from the first color. The second-color light emitting units 22 at least include a first light emitting unit 201 and a second light emitting unit 202. The first light emitting unit 201 and the second light emitting unit 202 in the second-color light emitting units 22 have a same light-exiting color, for example, both are the second color. The first light emitting unit 201 in the second-color light emitting units 22 and the first light emitting unit 201 in the first-color light emitting units 21 have different light-exiting colors. The second light emitting unit 202 in the second-color light emitting units 22 and the second light emitting unit 202 in the first-color light emitting units 21 have different light-exiting colors.

As shown in FIG. 1, along the directionh1 perpendicular to the plane of the substrate 1, the second-color filter 32 at least partially overlaps with the second-color light emitting unit 22. The light transmission waveband of the second-color filter 32 at least partially overlaps with a light-exiting waveband of the second-color light emitting unit 22 overlapping therewith.

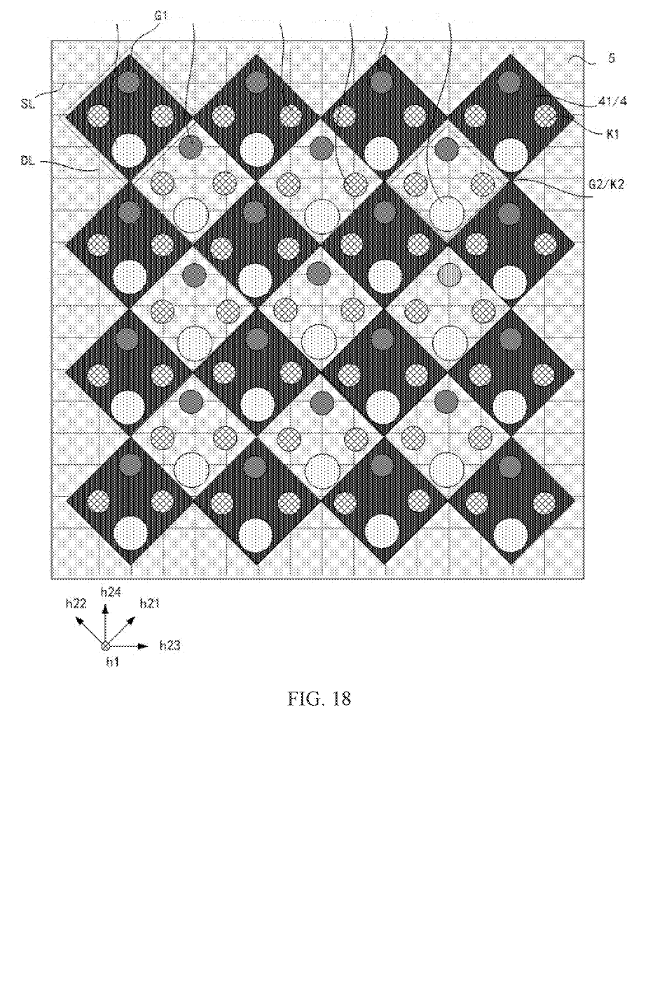

Exemplarily, as shown in FIG. 1 and FIG. 18, the display panel further includes a light shielding layer 4 located on a light-exiting side of the light emitting unit layer 2. The light shielding layer 4 includes a first light shielding portion 41, a first opening K1 and a second opening K2. The first light shielding portion 41 surrounds the first opening K1. Along the direction h1 perpendicular to the plane of the substrate 1, which is parallel to the thickness direction of the display panel, the first light shielding portion 41 at least partially does not overlap with the first light emitting unit 201, the first opening K1 at least partially overlaps with the first light emitting unit 201, and the second opening K2 at least partially overlaps with the second light emitting unit 202.

In the embodiments of the present disclosure, as shown in FIG. 1, the first light shielding portion 41 at least includes a first-color filter 31 and a second-color filter 32 that are stacked. As described above, the first-color filter 31 and the second-color filter 32 are of different colors. Therefore, the superposition of the first-color filter 31 and the second-color filter 32 can achieve a light shielding effect, so as to prevent large-angle light emitted by the first light emitting unit 201 from being emitted, which is conducive to realizing the large-view-angle privacy function of the display panel. FIG. 1 schematically illustrates that the first light shielding portion 41 includes a first-color filter 31 and a second-color filter 32 that are stacked.

In the embodiments of the present disclosure, each color of the color filter 3, such as the first-color filter 31 and the second-color filter 32 described above, may be understood as including two parts: a first part 301 and a second part 302. As shown in FIG. 1, in the direction h1 perpendicular to the plane of the substrate 1, the first part 301 of the first-color filter 31 may at least partially overlap with the first-color light emitting unit 21, and the first part 301 of the second-color filter 32 may at least partially overlap with the second-color light emitting unit 22. The second part 302 of the first-color filter 31 and the second part 302 of the second-color filter 32 may participate in forming the first light shielding portion 41.

As shown in FIG. 1, the first part 301 may be understood as including a first sub-part 3011 and a second sub-part 3012. In the direction h1 perpendicular to the plane of the substrate 1, the first sub-part 3011 of the first-color filter 31 may at least partially overlap with the first light emitting unit 201 in the first-color light emitting units 21, and the second sub-part 3012 of the first-color filter 31 may at least partially overlap with the second light emitting unit 202 in the first-color light emitting units 21. The first sub-part 3011 of the second-color filter 32 may at least partially overlap with the first light emitting unit 201 in the second-color light emitting units 22, and the second sub-part 3012 of the second-color filter 32 may at least partially overlap with the second light emitting unit 202 in the second-color light emitting units 22.

Exemplarily, as shown in FIG. 1, materials of the first sub-part 3011, the second sub-part 3012, and the second part 302 in the color filter 3 of a same color may be the same, and the three may be manufactured using a same process. When the materials of the three are the same and the three are manufactured using the same process, the three may be regarded as a whole, and the first sub-part 3011, the second sub-part 3012, and the second part 302 are merely different names given for ease of description according to differences in positions of the three.

In an embodiment, as shown in FIG. 1, the first-color filter 31 may not be hollowed out at the first opening K1 corresponding to the first-color light emitting unit 21, and the second-color filter 32 may not be hollowed out at the first opening K1 corresponding to the second-color light emitting unit 22.

It should be noted that, as shown in FIG. 1, the light shielding layer 4 may include first openings K1 and second openings K2. Some of the first openings K1 are formed corresponding to the first light emitting units 201 of the first-color light emitting units 21, and some other first openings K1 are formed corresponding to the first light emitting units 201 of the second-color light emitting units 22. Some of the second openings K2 are formed corresponding to the second light emitting units 202 of the first-color light emitting units 21, and some other second openings K2 are formed corresponding to the second light emitting units 202 of the second-color light emitting units 22. The widths of the first openings K1 corresponding to the light emitting units of different colors may be unequal. The widths of the second openings K2 corresponding to the light emitting units of different colors may be unequal.

When the display panel is in operation and the first light emitting unit 201 emits light, as shown in FIG. 1, the small-angle light emitted by the first light emitting unit 201, such as first light L11 shown in FIG. 1, may avoid the first light shielding portion 41 and be emitted out of the display panel through the first opening K1, so that a viewer at a relatively small viewing angle, such as a viewer at a front viewing angle, may view a display image. The small-angle light refers to light having an emission angle less than or equal to a first preset angle among the light emitted by the first light emitting unit 201. The first preset angle may be configured according to requirements of the privacy viewing angle of the display panel. The emission angle of the light is an included angle between the propagation direction and the normal of the substrate 1.

The large-angle light emitted by the first light emitting unit 201 may be blocked by the first light shielding portion 41 and cannot be emitted out of the display panel, thereby achieving the large-view-angle privacy effect of the display panel. The large-angle light refers to light having an emission angle greater than the first preset angle among the light emitted by the first light emitting unit 201. As an example, as shown in FIG. 1, second light L12 emitted by the first light emitting unit 201 may be blocked by the first light shielding portion 41 and cannot be emitted out of the display panel.

When the second light emitting unit 202 emits light, the small-angle light emitted by the second light emitting unit 202, such as third light L21 shown in FIG. 1, and the large-angle light emitted by the second light emitting unit 202, such as fourth light L22 shown in FIG. 1, may both be emitted out from the second opening K2.

In the display panel according to the embodiments of the present disclosure, by arranging the first light emitting unit 201 and the second light emitting unit 202 and cooperating with the arrangement of the first light shielding portion 41, when the first light emitting unit 201 emits light, a viewer at a large viewing angle cannot see the display image, that is, the display panel has the large-view-angle privacy effect. When the second light emitting unit 202 emits light, viewers at different viewing angles can see the display image, that is, the display panel has a sharing effect.

Based on such a configuration, while the display panel has the large-view-angle privacy effect, a privacy film does not need to be provided on the light-exiting side of the display panel, so that the thickness of the display panel can be reduced, and the lightweight and thin design of the display panel can be achieved. In addition, the embodiments of the present disclosure can realize convenient switching of the display panel between the privacy mode and the sharing mode by controlling the first light emitting unit 201 and the second light emitting unit 202 to be lit in a time-sharing manner.

In addition, when configuring the first light shielding portion 41, in the embodiments of the present disclosure, by configuring the first light shielding portion 41 to at least include the first-color filter 31 and the second-color filter 32 that are stacked, the forming processes of the display panel can be reduced, and the manufacturing costs of the display panel can be reduced.

In addition, the configuration of the first light shielding portion 41 may also reduce the reflectivity of the display panel.

Exemplarily, as shown in FIG. 1, the display panel further includes an array film layer 10. A pixel driving circuit (not shown) may be provided in the array film layer 10, and the pixel driving circuit is configured to drive the light emitting unit to be lit.

In an embodiment, as shown in FIG. 2a and FIG. 2b, FIG. 2a is a top-view schematic diagram of a display panel according to an embodiment of the present disclosure, and FIG. 2b is a sectional schematic diagram of FIG. 2a along CC’. The light shielding layer 4 includes a first light shielding layer 401 and a second light shielding layer 402 that is located on a side of the first light shielding layer 401 away from the substrate 1. The first light shielding layer 401 includes a first light shielding sub-portion 411, a first sub-opening K11, and a second sub-opening K21, and the first light shielding sub-portion 411 surrounds the first sub-opening K11. The second light shielding layer 402 includes a second light shielding sub-portion 412, a third sub-opening K12, and a fourth sub-opening K22. The second light shielding sub-portion 412 surrounds the third sub-opening K12. Along the direction h1 perpendicular to the plane of the substrate 1, the first light shielding sub-portion 411 and the second light shielding sub-portion 412, and the first light emitting unit 201 at least partially do not overlap; the first sub-opening K11 and the third sub-opening K12, and the first light emitting unit 201 at least partially overlap; and the second sub-opening K21 and the fourth sub-opening K22, and the second light emitting unit 202 at least partially overlap.

The first light shielding portion 41 includes the first light shielding sub-portion 411 and the second light shielding sub-portion 412. The first opening K1 includes the first sub-opening K11 and the third sub-opening K12. The second opening K2 includes the second sub-opening K21 and the fourth sub-opening K22.

When the display panel is in operation, the small-angle light emitted by the first light emitting unit 201, such as the first light L11 shown in FIG. 2b, may be emitted out of the display panel through the first sub-opening K11 and the third sub-opening K12; and the small-angle light emitted by the second light emitting unit 202, such as the third light L21 shown in FIG. 2b, may be emitted out of the display panel through the second sub-opening K21 and the fourth sub-opening K22.

The large-angle light emitted by the first light emitting unit 201 may be blocked by the first light shielding layer 401 or the second light shielding layer 402 and cannot be emitted out of the display panel, thereby achieving the large-view-angle privacy effect of the display panel. As an example, as shown in FIG. 2b, first sub-light L121 emitted by the first light emitting unit 201 may be blocked by the first light shielding layer 401 and cannot be emitted out of the display panel, and second sub-light L122 may be blocked by the second light shielding layer 402 and cannot be emitted out of the display panel. The emission angle of the second sub-light L122 is less than the emission angle of the first sub-light L121.

In the embodiments of the present disclosure, by configuring the first light shielding layer 401 and the second light shielding layer 402, the first light shielding layer 401 and the second light shielding layer 402 can jointly limit the viewing angle of the display panel, which can realize the large-view-angle privacy effect of the display panel, and reduce the width of the first light shielding layer 401 and the second light shielding layer 402 required for privacy, thereby reducing the distance P between two adjacent light emitting units, improving the Pixels Per Inch (PPI) of the display panel, and increasing the privacy angle range. In addition, the viewing angle range in the sharing mode may also be increased.

Exemplarily, as shown in FIG. 1, FIG. 2a and FIG. 2b, the display panel further includes a pixel definition layer 5.

It should be noted that, in FIG. 2a, the staggered arrangement of the pixel definition layer 5, the first-color filter 31, the second-color filter 32 and the second light shielding layer 402 at edge positions is merely for more clearly distinguishing different film layers. In an actual structure, such staggered design may not exist among the film layers.

As shown in FIG. 1, FIG. 2a and FIG. 2b, the pixel definition layer 5 includes a first pixel opening 51 and a second pixel opening 52. At least part of the first light emitting unit 201 is located in the first pixel opening 51. At least part of the second light emitting unit 202 is located in the second pixel opening 52.

Exemplarily, taking FIG. 2b as an example, each of the first light emitting unit 201 and the second light emitting unit 202 includes a first electrode E1, a light emitting layer E0 and a second electrode E2 that are stacked. In an embodiment, one of the first electrode E1 and the second electrode E2 is an anode, and the other one of the first electrode E1 and the second electrode E2 is a cathode. Exemplarily, in the embodiments of the present disclosure, the first electrode E1 may be electrically connected to a pixel driving circuit (not shown in FIG. 1). When the display panel is in operation, the light emitting layer E0 can emit light of a predetermined color under the action of the voltage difference between the first electrode E1 and the second electrode E2. The light-exiting color of the light emitting unit 20 refers to the light-exiting color of the light emitting layer E0.

Exemplarily, the light emitting layer E0 includes any one of an organic light emitting material, a quantum dot light emitting material, and an inorganic light emitting material. The material of the light emitting layer E0 is not specifically limited in the embodiments of the present disclosure.

That at least part of the first light emitting unit 201 is located in the first pixel opening 51, and at least part of the second light emitting unit 202 is located in the second pixel opening 52 may be understood as follows: the light emitting layer E0 of the first light emitting unit 201 is at least partially located in the first pixel opening 51, and the light emitting layer E0 of the second light emitting unit 202 is at least partially located in the second pixel opening 52.

As shown in FIG. 2b, along the first direction h21, the shortest distance between the edge of the first pixel opening 51 and the edge of the first sub-opening K11 is d11, and the shortest distance between the edge of the first pixel opening 51 and the edge of the third sub-opening K12 is d21, where d11 > d21. The first direction h21 is parallel to the plane of the substrate 1. By adopting such a configuration, when the first light emitting unit 201 emits light, the first light shielding layer 401 may be used to block light having a larger light-exiting angle emitted by the first light emitting unit 201, and the second light shielding layer 402 may be used to block light having a slightly smaller light-exiting angle emitted by the first light emitting unit 201, thereby ensuring the privacy effect of the display panel in the privacy mode. In addition, the width of the first light shielding layer 401 and the second light shielding layer 402 may also be reduced, which is beneficial to reducing the distance P between two adjacent pixel openings.

Exemplarily, as shown in FIG. 2b, along the first direction h21, the shortest distance between the edge of the second pixel opening 52 and the edge of the second sub-opening K21 is d12, and the shortest distance between the edge of the second pixel opening 52 and the edge of the fourth sub-opening K22 is d22, where d22 > d12. By adopting such a configuration, when the second light emitting unit 202 emits light, light emitted from the second sub-opening K21 can continue to smoothly pass through the fourth sub-opening K22, which is beneficial to increasing the exiting light of the second light emitting unit 202 and ensuring that the display panel has a large viewing angle in the sharing mode.

Exemplarily, as shown in FIG. 2b, along the first directionh21, the width of the first sub-opening K11 is W11, the width of the third sub-opening K12 is W21, and the width of the first pixel opening 51 is W01, where W11 ≥ W21 ≥ W01. By adopting such a configuration, when the first light emitting unit 201 emits light, the first light shielding layer 401 may be used to block light having a larger light-exiting angle emitted by the first light emitting unit 201, and the second light shielding layer 402 may be used to block light having a slightly smaller light-exiting angle emitted by the first light emitting unit 201, thereby ensuring the privacy effect of the display panel in the privacy mode. In addition, the width of the first light shielding layer 401 and the second light shielding layer 402 may also be reduced, which is beneficial to reducing the distance between two adjacent light emitting units, or increasing the area of the pixel opening.

Still referring to FIG. 2b, along the first direction h21, the width of the second sub-opening K21 is W12, the width of the fourth sub-opening K22 is W22, and the width of the second pixel opening 52 is W02, where W22 > W12 ≥ W02. By adopting such a configuration, when the second light emitting unit 202 emits light, light emitted from the second sub-opening K21 can continue to smoothly pass through the fourth sub-opening K22, which is beneficial to increasing the exiting light of the second light emitting unit 202 and ensuring that the display panel has a large viewing angle in the sharing mode.

Exemplarily, W11 - W21 ≤ 3 μm. Adopting such a configuration can avoid the excessive difference between the width of the first sub-opening K11 and the width of the third sub-opening K12, ensure the overlapping area of the first light shielding layer 401 and the second light shielding layer 402 in the directionh1 perpendicular to the plane of the substrate 1, and prevent part of large-angle light emitted by the first light emitting unit 201 from leaking out from between the first light shielding layer 401 and the second light shielding layer 402, which is beneficial to ensuring the privacy effect of the display panel.

In the embodiments of the present disclosure, W12 - W02 > 10 μm may be configured to ensure the light-exiting angle of the second light emitting unit 202 and ensure that the display panel has a relatively large viewing angle in the sharing mode.

Exemplarily, as shown in FIG. 2b, the first light shielding layer 401 includes a first-color filter 31 and a second-color filter 32 that are stacked. The second light shielding layer 402 includes a black matrix (BM) 400. As an example, the first light shielding sub-portion 411 in the first light shielding layer 401 includes the first-color filter 31 and the second-color filter 32 that are stacked. The second light shielding sub-portion 412 in the second light shielding layer 402 includes the black matrix 400. In the embodiments of the present disclosure, the black matrix 400 has relatively low transmittance for light of both the first color and the second color. Exemplarily, the black matrix 400 includes a black light shielding material, such as carbon black, chromium, chromium oxide, or black resin.

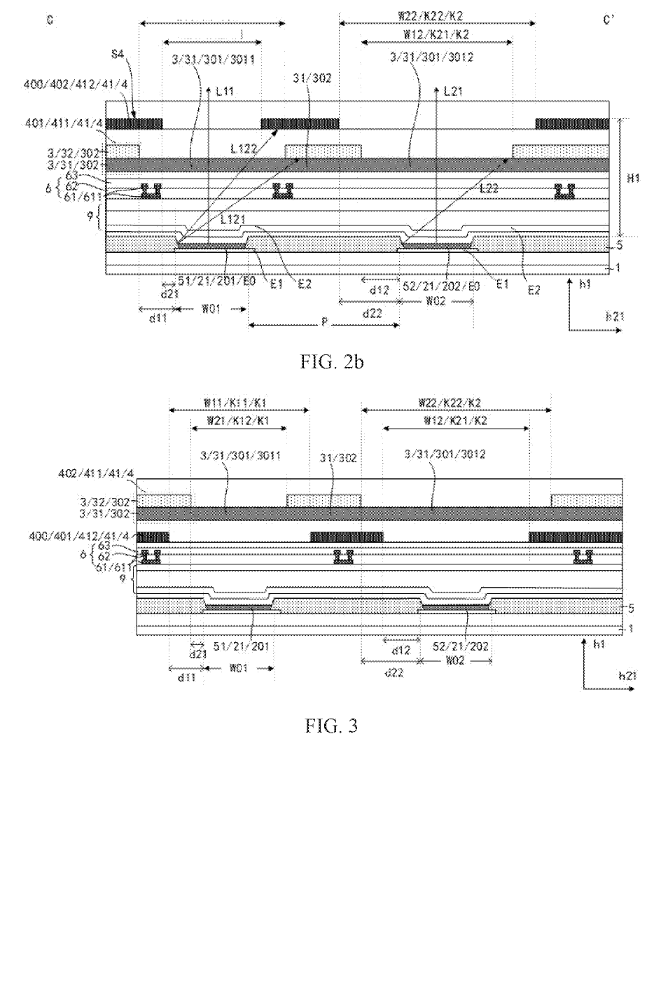

Alternatively, as shown in FIG. 3, which is a sectional schematic diagram of another display panel according to an embodiment of the present disclosure, the first light shielding layer 401 includes a black matrix 400, and the second light shielding layer 402 includes the first-color filter 31 and the second-color filter 32. The first-color filter 31 and the second-color filter 32 are stacked. Adopting such a configuration can avoid residues of the black matrix 400 in a terminal region of the display panel, thereby avoiding short-circuit or open-circuit problems caused by the black matrix 400 in the terminal region, and helping ensure the display effect of the display panel. The terminal region refers to a region in the non-display region of the display panel for being bonded and connected to a flexible circuit board, and the terminal region is provided with a signal transmission pin.

For example, as shown in FIG. 3, along the first direction h21, the width of the first sub-opening K11 is W11, the width of the third sub-opening K12 is W21, the width of the first pixel opening 51 is W01, the width of the second sub-opening K21 is W12, the width of the fourth sub-opening K22 is W22, and the width of the second pixel opening 52 is W02, satisfying: W11 ≥ W21 ≥ W01, and W22 > W12≥ W02.

In an implementation, in the embodiments of the present disclosure, W01 ≥ W02.

Alternatively, in another optional implementation, in the embodiments of the present disclosure, W01 ≤ W02.

In an embodiment, as shown in FIG. 2b and FIG. 3, the display panel further includes a touch layer 6 located between the light shielding layer 4 and the light emitting unit layer 2. The touch layer 6 includes at least one touch metal layer 61 and at least one touch insulating layer 62. The touch metal layer 61 includes a touch metal trace 611. Along the directionh1 perpendicular to the plane of the substrate 1, the touch metal trace 611 at least partially overlaps with the black matrix 400. By adopting such a configuration, the black matrix 400 may be configured to absorb incident light from an external environment and absorb light reflected by the touch metal trace 611, so as to reduce the visibility of the touch metal trace 611, which is beneficial to improving the display effect of the display panel.

Exemplarily, as shown in FIG. 2b and FIG. 3, the touch layer 6 may further include an organic insulating layer 63 located on a side of the touch layer 6 close to the color filter 3. Exemplarily, the organic insulating layer 63 includes an optical adhesive layer.

Exemplarily, as shown in FIG. 2b, when the black matrix 400 is arranged on a side, away from the substrate 1, of the first-color filter 31 and the second-color filter 32 that are stacked in the first light shielding portion 41, since the black matrix 400 has a portion exceeding the first-color filter 31 and the second-color filter 32 that are stacked in the first light shielding portion 41, along the direction h1 perpendicular to the plane of the substrate 1, in the embodiments of the present disclosure, the touch metal trace 611 may overlap with the above-mentioned exceeding portion in the black matrix 400. The exceeding portion refers to a portion in the black matrix 400 exceeding the first-color filter 31 and the second-color filter 32 that are stacked in the first light shielding portion 41.

Alternatively, along the direction h1 perpendicular to the plane of the substrate 1, in the embodiments of the present disclosure, the touch metal trace 611 may overlap with the black matrix 400, and the first-color filter 31 and the second-color filter 32 that are stacked in the first light shielding portion 41. As shown in FIG. 3, when the black matrix 400 is arranged on a side, close to the substrate 1, of the first-color filter 31 and the second-color filter 32 that are stacked in the first light shielding portion 41, along the direction h1 perpendicular to the plane of the substrate 1, the black matrix 400 may be covered by the first-color filter 31 and the second-color filter 32 that are stacked in the first light shielding portion 41. Therefore, the touch metal trace 611 may overlap with the black matrix 400, and the first-color filter 31 and the second-color filter 32 that are stacked in the first light shielding portion 41.

Exemplarily, the thickness of the first-color filter 31 at least partially overlapping with the first-color light emitting unit 21 is less than or equal to the thickness of the first-color filter 31 in the first light shielding portion 41. FIG. 1, FIG. 2b, and FIG. 3 each schematically illustrate equality.

In another optional implementation, as shown in FIG. 4, which is a sectional schematic diagram of another display panel according to an embodiment of the present disclosure, it is schematically illustrated that the thickness of the first-color filter 31 at least partially overlapping with the first-color light emitting unit 21 is smaller than the thickness of the first-color filter 31 in the first light shielding portion 41. By adopting such a configuration, the first-color filter 31 in the first light shielding portion 41 has stronger light shielding capability, which is beneficial to improving the light shielding capability of the first light shielding portion 41, thereby improving the shielding capability for the large-angle light emitted by the first light emitting unit 201, and ensuring the privacy effect in the privacy mode. Further, as shown in FIG. 4, when the light shielding layer 4 is arranged to include the first light shielding layer 401 and the second light shielding layer 402, the thickness of the first light shielding layer 401 is increased by adopting the configuration according to the embodiments of the present disclosure, so that more large-angle light emitted by the first light emitting unit 201 can be shielded by the first light shielding layer 401, and the width of the second light shielding layer 402 can be appropriately reduced, thereby ensuring the privacy effect, and avoiding shielding of required light, such as small-angle light emitted by the first light emitting unit 201 and large-angle light emitted by the second light emitting unit 202, caused by the excessively large width of the second light shielding layer 402. In this way, it can ensure the large-view-angle brightness of the display panel in the sharing mode and the small-view-angle brightness of the display panel in the privacy mode.

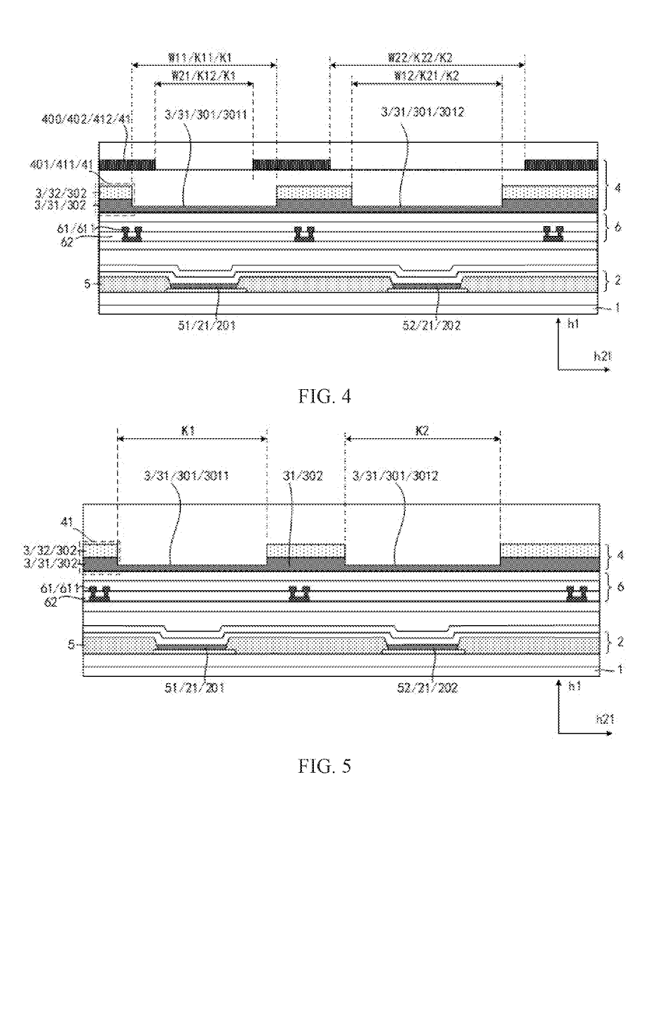

In an embodiment, as shown in FIG. 5, which is a sectional schematic diagram of another display panel according to an embodiment of the present disclosure, the black matrix 400 may further be removed on the basis of FIG. 4, so as to simplify the preparation processes of the display panel and to reduce the thickness of the display panel.

Exemplarily, as shown in FIG. 4 and FIG. 5, the first-color filter 31 at least partially overlapping with the first-color light emitting unit 21 and the first-color filter 31 in the first light shielding portion 41 may be formed using a same process. That is, the first part 301 and the second part 302 in the first-color filter 31 may be formed using a same process.

For example, materials of the first part 301 and the second part 302 in the first-color filter 31 are the same. When forming the first part 301 and the second part 302 in the first-color filter 31, a first-color filter material layer may first be formed by a film forming process, and an orthographic projection of the first-color filter material layer on the plane of the substrate 1 may cover the substrate 1. Then, the first-color filter material layer in the region where the first-color filter 31 does not need to be formed may be removed by a patterning process, and the retained part of the first-color filter material layer may respectively form the first part 301 and the second part 302.

Exemplarily, the patterning process may include an exposure process, and the exposure process may adopt a half-tone mask, so as to form the first part 301 and the second part 302 having different thicknesses in the same process.

Exemplarily, as shown in FIG. 4 and FIG. 5, the bottom surface of the first part 301 of the first-color filter 31 and the bottom surface of the second part 302 of the first-color filter 31 may be coplanar.

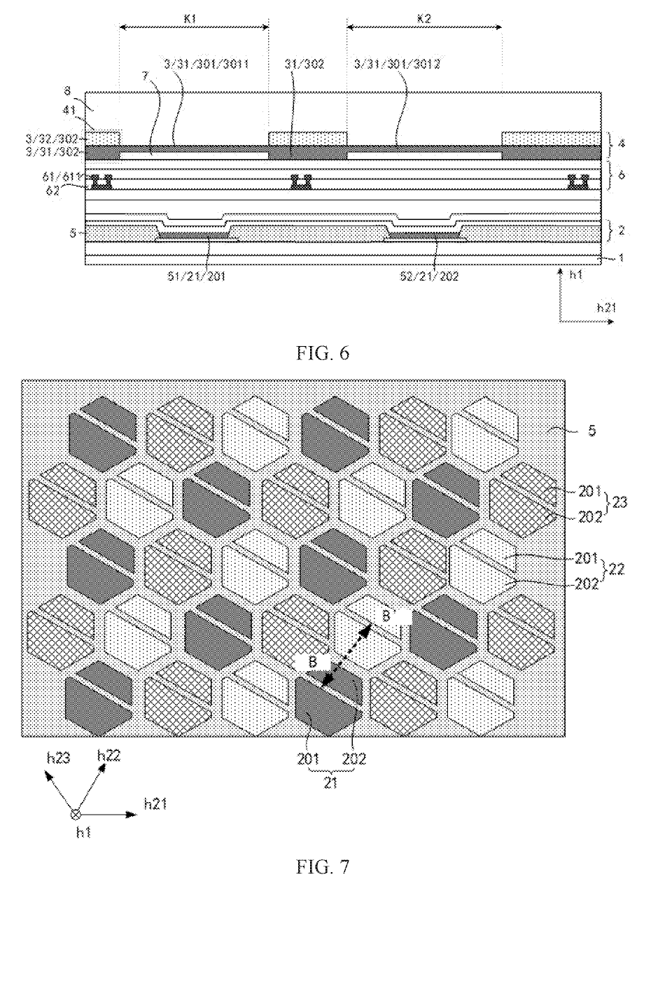

In another optional implementation, as shown in FIG. 6, FIG. 6 is a sectional schematic diagram of another display panel according to an embodiment of the present disclosure, the display panel further includes a transparent cushion layer 7. Along the direction h1 perpendicular to the plane of the substrate 1, the transparent cushion layer 7 at least partially overlaps with the first-color light emitting unit 21, and is located on a side of the first-color filter 31 close to the substrate 1. As an example, as shown in FIG. 6, the transparent cushion layer 7 is located on a side, close to the substrate 1, of the first-color filter 31 at least partially overlapping with the first-color light emitting unit 21, that is, of the first part 301.

When forming the display panel, the transparent cushion layer 7 may be formed first, and then the first-color filter 31 is formed.

Exemplarily, by adopting such a configuration, the first-color filter material layer may be exposed using a full-tone mask, and the first part 301 and the second part 302 in the first-color filter 31 may be formed in a same process.

Exemplarily, as shown in FIG. 6, the display panel further includes an optical adhesive layer 8, and at least part of the optical adhesive layer 8 may be located in the first opening K1 and the second opening K2, and at least another part of the optical adhesive layer 8 may cover an upper surface of the first light shielding portion 41.

Exemplarily, as shown in FIG. 7, FIG. 7 is a top-view schematic diagram of a display panel according to an embodiment of the present disclosure, in addition to the first-color light emitting units 21 and the second-color light emitting units 22, the light emitting unit layer 2 further includes third-color light emitting units 23 including a first light emitting unit 201 and a second light emitting unit 202. In addition, the light-exiting color of the first light emitting unit 201 and the second light emitting unit 202 in the first-color light emitting units 21, the light-exiting color of the first light emitting unit 201 and the second light emitting unit 202 in the second-color light emitting units 22, and the light-exiting color of the first light emitting unit 201 and the second light emitting unit 202 in the third-color light emitting units 23 are different from one another.

Being different from one another includes: the light-exiting color of the first light emitting unit 201 in the first-color light emitting units 21 being different from the light-exiting color of the first light emitting unit 201 in the second-color light emitting units 22; the light-exiting color of the first light emitting unit 201 in the first-color light emitting units 21 being different from the light-exiting color of the first light emitting unit 201 in the third-color light emitting units 23; the light-exiting color of the first light emitting unit 201 in the second-color light emitting units 22 being different from the light-exiting color of the first light emitting unit 201 in the third-color light emitting units 23; the light-exiting color of the second light emitting unit 202 in the first-color light emitting units 21 being different from the light-exiting color of the second light emitting unit 202 in the second-color light emitting units 22; the light-exiting color of the second light emitting unit 202 in the first-color light emitting units 21 being different from the light-exiting color of the second light emitting unit 202 in the third-color light emitting units 23; and the light-exiting color of the second light emitting unit 202 in the second-color light emitting units 22 being different from the light-exiting color of the second light emitting unit 202 in the third-color light emitting units 23.

That the first light emitting unit 201 and the second light emitting unit 202 in a same-color light emitting unit have the same color means that the light-exiting color of the first light emitting unit 201 in the first-color light emitting units 21 is the same as the light-exiting color of the second light emitting unit 202 in the first-color light emitting units 21. The light-exiting color of the first light emitting unit 201 in the second-color light emitting units 22 is the same as the light-exiting color of the second light emitting unit 202 in the second-color light emitting units 22. The light-exiting color of the first light emitting unit 201 in the third-color light emitting units 23 is the same as the light-exiting color of the second light emitting unit 202 in the third-color light emitting units 23.

As shown in FIG. 7, along the first directionh21, the first-color light emitting units 21, the second-color light emitting units 22 and the third-color light emitting units 23 are arranged alternately in sequence. Along the second direction h22, the first-color light emitting units 21, the second-color light emitting units 22 and the third-color light emitting units 23 are arranged alternately in sequence. Along the third direction h23, the first-color light emitting units 21, the second-color light emitting units 22 and the third-color light emitting units 23 are arranged alternately in sequence. The first directionh21, the second direction h22 and the third direction h23 are all parallel to the plane of the substrate 1, and are all perpendicular to the direction h1 perpendicular to the plane of the substrate 1. Any two of the first direction h21, the second direction h22 and the third direction h23 intersect with each other.

By adopting such a configuration, a light emitting unit of any color and another light emitting unit adjacent thereto in the first direction h21, the second direction h22, and the third directionh23 may have different light-exiting colors.

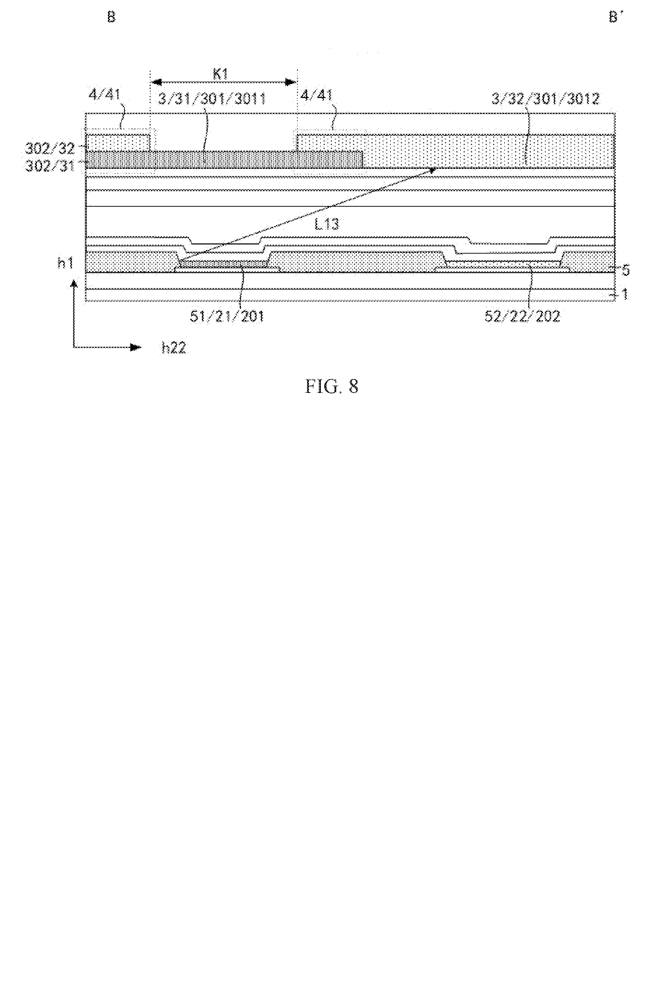

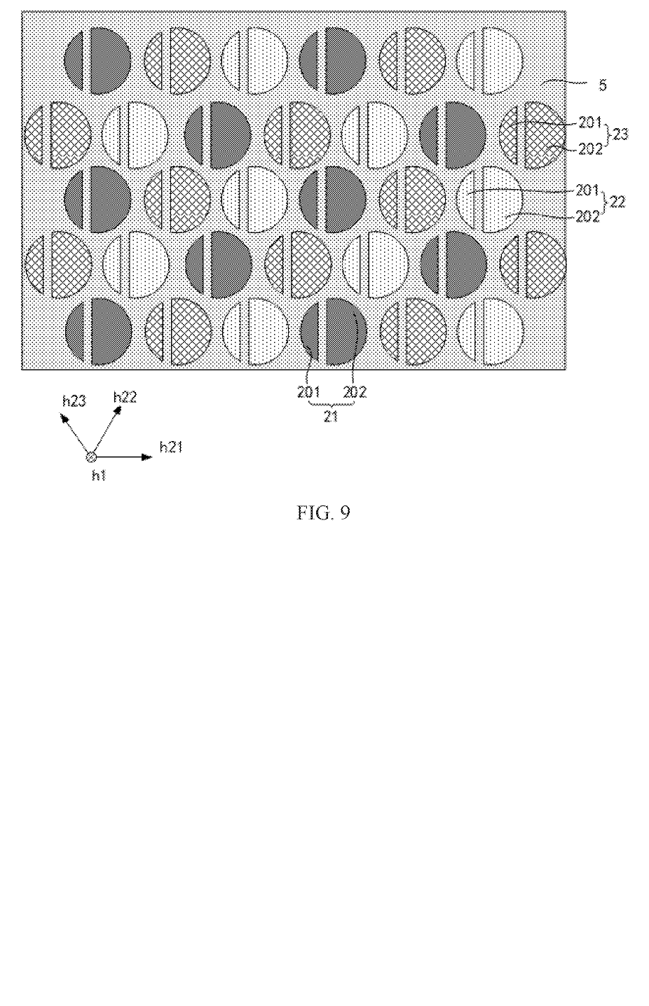

As shown in FIG. 7 and FIG. 8, FIG. 8 is a sectional schematic diagram of FIG. 7 along BB’, for part of large-angle light emitted by the first light emitting unit 201 of the first-color light emitting unit 21, such as fifth light L13 shown in FIG. 8, although it avoids the first light shielding portion 41 corresponding to the first light emitting unit 201, it may be incident to a region where the second-color light emitting unit 22 adjacent to the first light emitting unit 201 is located. In the embodiments of the present disclosure, the second-color light emitting unit 22 and the first-color light emitting unit 21 are of different colors. The second-color filter 32 is arranged above the second-color light emitting unit 22. The second-color filter 32 at least partially overlaps with the second-color light emitting unit 22. Therefore, when the above-mentioned light L13 of the first color is incident to the second-color filter 32, it is blocked by the second-color filter 32 and cannot be emitted out of the display panel.

Exemplarily, as shown in FIG. 8, based on such a configuration, the first-color filter 31 in the first light shielding portion 41 may be formed simultaneously by the same process as the first-color filter 31 at least partially overlapping with the first-color light emitting unit 21, and the second-color filter 32 in the first light shielding portion 41 may be formed simultaneously by the same process as the second-color filter 32 at least partially overlapping with the second-color light emitting unit 22, which can reduce the preparation processes of the display panel, reduce the manufacturing costs of the display panel, and facilitate reducing the thickness of the display panel. In addition, by adopting such a configuration, while ensuring the privacy effect of the display panel, it is also beneficial to increasing the area of the light emitting unit, reducing the distance between two adjacent light emitting units, and improving the PPI of the display panel.

Exemplarily, as shown in FIG. 7, in the first-color light emitting units 21, the width of the first light emitting unit 201 is less than the width of the second light emitting unit 202 in the same direction. In the second-color light emitting units 22, the width of the first light emitting unit 201 is less than the width of the second light emitting unit 202 in the same direction. In the third-color light emitting units 23, the width of the first light emitting unit 201 is less than the width of the second light emitting unit 202 in the same direction. FIG. 7 schematically illustrates that the width direction of each light emitting unit is parallel to the second direction h22.

In the embodiments of the present disclosure, by reducing the width of the first light emitting unit 201, it is beneficial to reducing the light-exiting angle of the first light emitting unit 201, thereby reducing the viewing angle of the display panel in the privacy mode, and ensuring the privacy effect of the display panel in the privacy mode. In addition, in the embodiments of the present disclosure, by increasing the width of the second light emitting unit 202, it is beneficial to increasing the light-exiting angle of the second light emitting unit 202, thereby increasing the viewing angle of the display panel in the sharing mode and ensuring the display effect of the display panel in the sharing mode.

It should be noted that the width of the light emitting unit may be understood as the width of the pixel opening corresponding to the light emitting unit in the same direction. The width of the first light emitting unit 201 is smaller than the width of the second light emitting unit 202 in the same direction, that is, the width of the first pixel opening 51 corresponding to the first light emitting unit 201 is smaller than the width of the second pixel opening 52 corresponding to the second light emitting unit 202.

Exemplarily, as shown in FIG. 7, the first light emitting unit 201 and the second light emitting unit 202 in a same-color light emitting unit may be regarded as being obtained by dividing one light emitting unit having a larger area. By adopting such a configuration, the resolution of the display panel does not need to be reduced while the display panel has the privacy function.

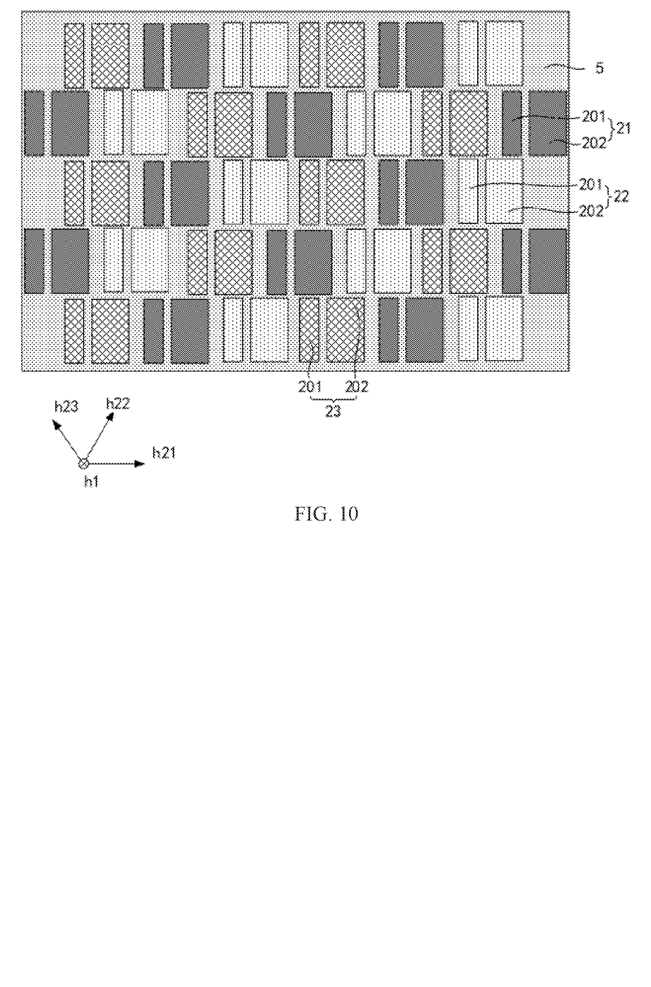

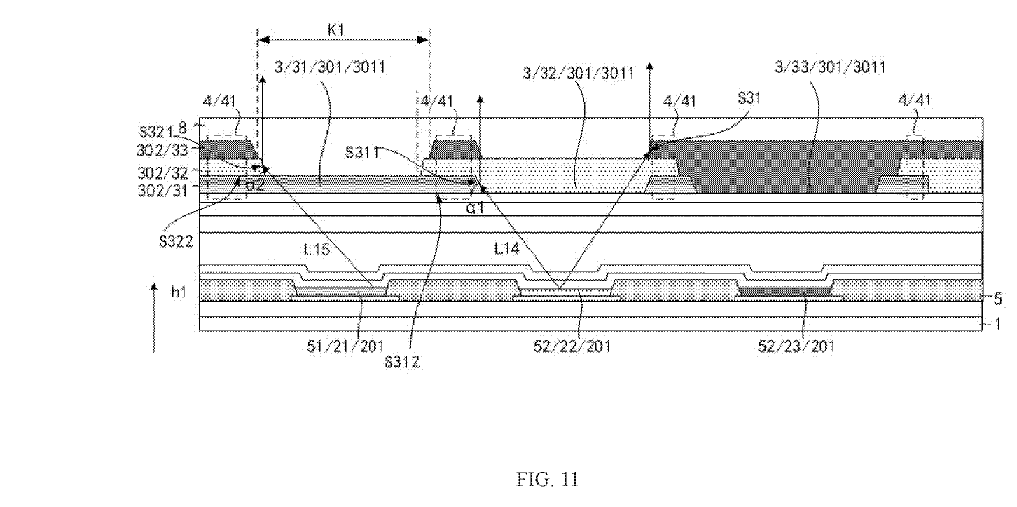

It should be noted that the shapes of the light emitting units shown in FIG. 7 are merely schematic. In the embodiments of the present disclosure, the shapes of the light emitting units may also be designed as other shapes according to different design requirements. The shape of the light emitting unit may be defined by the shape of the pixel opening. Designing the shape of the light emitting unit as another shape means designing the shape of the pixel opening as another shape. For example, as shown in FIG. 9 and FIG. 10, FIG. 9 and FIG. 10 are respectively top-view schematic diagrams of two other display panels according to an embodiment of the present disclosure. FIG. 9 schematically illustrates that the first light emitting unit 201 and the second light emitting unit 202 in a light emitting units of a same color together form a circular shape, and FIG. 10 schematically illustrates that the first light emitting unit 201 and the second light emitting unit 202 in a light emitting units of a same color together form a rectangular shape.

As shown in FIG. 1, FIG. 2b, FIG. 3, FIG. 4, FIG. 5, FIG. 6 and FIG. 8, in the direction h1 perpendicular to the plane of the substrate 1, two adjacent color filters 3 in the first light shielding portion 41 are in contact with each other. By adopting such a configuration, the thickness of the first light shielding portion 41 in the direction h1 perpendicular to the plane of the substrate 1 can be reduced, thereby reducing the thickness of the display panel and facilitating the thin design of the display panel.

Exemplarily, as shown in FIG. 2b, in the embodiments of the present disclosure, the first light shielding layer 401 and the second light shielding layer 402 may be arranged in the light shielding layer 4, and one of the first light shielding layer 401 and the second light shielding layer 402 may include the first-color filter 31 and the second-color filter 32 that are stacked. The first-color filter 31 and the second-color filter 32 that are stacked are in contact with each other. The distance H1 between the surface S4 of the light shielding layer 4 away from the substrate 1 and the light emitting unit 20 in the direction h1 perpendicular to the plane of the substrate 1 may be increased by the other one of the first light shielding layer 401 and the second light shielding layer 402.

The distance H1, the width of the light emitting unit and the distance between the light emitting unit and the first light shielding portion 41 jointly affect the light-exiting angle of the light emitting unit. The larger the distance H1 is, the smaller the emission angle of light emitted through the first opening K1 is, which is more conducive to make an improvement in terms of the privacy viewing angle.

Based on the configuration shown in FIG. 2b, the surface S4 of the second light shielding layer 402 away from the substrate 1 is the surface of the light shielding layer 4 away from the substrate 1. After the first-color filter 31 and the second-color filter 32 that are stacked are arranged to be in contact with each other, the distance H1 between the surface S4 of the second light shielding layer 402 away from the substrate 1 and the light emitting unit 20 may be adjusted, so that the privacy viewing angle meets the requirements.

Exemplarily, as shown in FIG. 2b, a touch layer 6 and an encapsulation layer 9 are further provided between the light emitting unit layer 2 and the light shielding layer 4. The distance H1 includes the sum of the thickness of the touch layer 6, the thickness of the encapsulation layer 9, and the thickness of the light shielding layer 4. When the light shielding layer 4 includes film layers that are stacked, for example, if an optical adhesive layer is formed between the film layers, the distance H1 further includes the thickness of the optical adhesive layer.

In the implementation illustrated in FIG. 4, in the embodiments of the present disclosure, the thickness of the first-color filter 31 at least partially overlapping with the first-color light emitting unit 21 may be less than or equal to the thickness of the first-color filter 31 in the first light shielding portion 41, so as to increase the thickness of the first light shielding portion 41, to ensure that the upper surface of the first light shielding portion 41 and the light emitting unit have a large enough distance in the direction h1 perpendicular to the plane of the substrate 1, and to meet the requirements of the privacy viewing angle.

Alternatively, in the embodiments of the present disclosure, the light emitting units may be arranged according to the rule shown in FIG. 7, that is, the first-color light emitting units 21, the second-color light emitting units 22, and the third-color light emitting units 23 are all arranged alternately in sequence along the first direction h21, the second direction h22, and the third direction h23. By using the characteristic that the color filter 3 located directly above the light emitting unit can block large-angle light of a different color emitted from another adjacent light emitting unit, the privacy effect of the display panel can be ensured without increasing the thickness of the display panel.

In an embodiment, as shown in FIG. 11, FIG. 11 is a sectional schematic diagram of another display panel according to an embodiment of the present disclosure. The first light shielding portion 41 further includes a third-color filter 33. The first-color filter 31, the second-color filter 32 and the third-color filter 33 are stacked, and colors of the first-color filter 31, the second-color filter 32 and the third-color filter 33 are different from one another. That is, the transmission wavebands of the first-color filter 31, the second-color filter 32, and the third-color filter 33 do not overlap with one another. The light transmission waveband of the third-color filter 33 at least partially overlaps with the light-exiting waveband of the third-color light emitting unit 23 overlapping therewith. By adopting such a configuration, the light transmittance of the first light shielding portion 41 can be further reduced, and the light shielding performance of the first light shielding portion 41 can be improved.

Exemplarily, as shown in FIG. 11, similar to the above-mentioned division of the first-color filter 31 and the second-color filter 32, the third-color filter 33 may also include a first part 301 and a second part 302. The first part 301 at least partially overlaps with the third-color light emitting unit 23 in the direction h1 perpendicular to the plane of the substrate 1. The second part 302 may at least partially overlap with the first-color filter 31 in the direction h1 perpendicular to the plane of the substrate 1, so as to form the first light shielding portion 41.

Further, in the third-color filter 33, the first part 301 may also include a first sub-part 3011 and a second sub-part 3012. The first sub-part 3011 may at least partially overlap with the first light emitting unit 201 in the third-color light emitting units 23 in the direction h1 perpendicular to the plane of the substrate 1. The second sub-part 3012 may at least partially overlap with the second light emitting unit 202 in the third-color light emitting units 23 in the direction h1 perpendicular to the plane of the substrate 1.

FIG. 11 only schematically illustrates the first light emitting unit 201 in the first-color light emitting units 21, the first light emitting unit 201 in the second-color light emitting units 22, and the first light emitting unit 201 in the third-color light emitting units 23 in the light emitting unit layer 2; and only schematically illustrates the first sub-part 3011 at least partially overlapping with the first light emitting unit 201 in the first-color light emitting units 21 in the direction h1 perpendicular to the plane of the substrate 1 in the first part 301 of the first-color filter 31, only schematically illustrates the first sub-part 3011 at least partially overlapping with the first light emitting unit 201 in the second-color light emitting units 22 in the direction h1 perpendicular to the plane of the substrate 1 in the first part 301 of the second-color filter 32, and only schematically illustrates the first sub-part 3011 at least partially overlapping with the first light emitting unit 201 in the third-color light emitting units 23 in the direction h1 perpendicular to the plane of the substrate 1 in the first part 301 of the third-color filter 33.

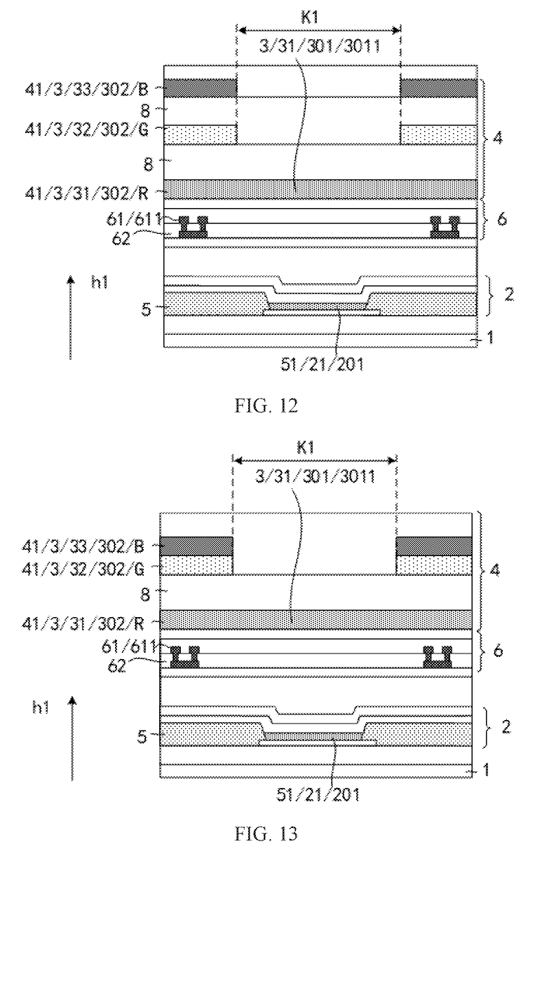

Exemplarily, as shown in FIG. 12, FIG. 12 is a sectional schematic diagram of another display panel according to an embodiment of the present disclosure. In the direction h1 perpendicular to the plane of the substrate 1, an optical adhesive layer 8 is provided between at least two adjacent color filters 3 in the first light shielding portion 41. The arrangement of the optical adhesive layer 8 may increase the distance between a color filter 3 located above the optical adhesive layer 8 in the first light shielding portion 41 and the first light emitting unit 201, which is beneficial to causing more large-angle light emitted by the first light emitting unit 201 to be incident to the first light shielding portion 41, and ensuring the large-view-angle privacy effect of the display panel.

FIG. 12 schematically illustrates that the first light shielding portion 41 includes the first-color filter 31, the second-color filter 32 and the third-color filter 33 having colors different from one another. An optical adhesive layer 8 is provided between the first-color filter 31 and the second-color filter 32, and an optical adhesive layer 8 is provided between the second-color filter 32 and the third-color filter 33.

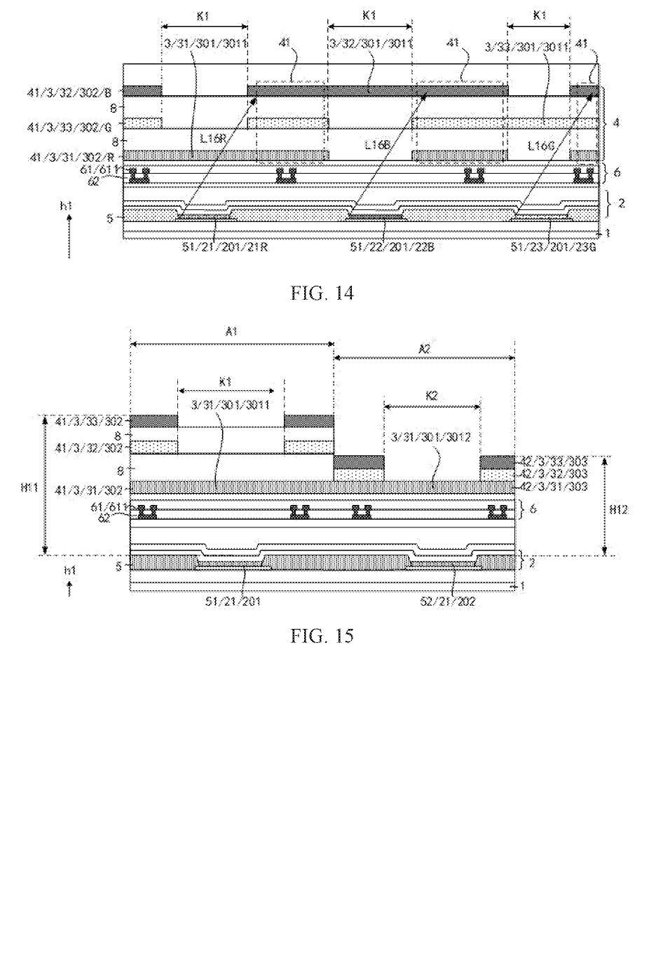

Exemplarily, as shown in FIG. 13, FIG. 13 is a sectional schematic diagram of another display panel according to an embodiment of the present disclosure, and schematically illustrates that an optical adhesive layer 8 is provided between the first-color filter 31 and the second-color filter 32, and the second-color filter 32 is in contact with the third-color filter 33.

Exemplarily, as shown in FIG. 14, FIG. 14 is a sectional schematic diagram of another display panel according to an embodiment of the present disclosure, the first-color light emitting units 21 includes a red light emitting unit 21R, and the first-color filter 31 includes a red color filter R. The light emitting unit layer 2 further includes a blue light emitting unit 22B. In an embodiment, the second-color light emitting units 22 may include the blue light emitting unit 22B. In the embodiments of the present disclosure, the blue light emitting unit 22B also include a first light emitting unit 201 and a second light emitting unit (not shown in FIG. 14). The second-color filter 32 includes a blue color filter B. Along the direction h1 perpendicular to the plane of the substrate 1, the distance between the blue color filter B and the substrate 1 is greater than the distance between the red color filter R and the substrate 1. That is, the blue color filter B is arranged on a side of the red color filter R away from the substrate 1. FIG. 14 schematically illustrates that the light emitting unit layer 2 further includes a green light emitting unit 23G, and the color filter 3 further includes a green color filter G. The blue color filter B is located on a side of the green color filter G away from the red color filter R.

Based on the configuration shown in FIG. 14, since two adjacent color filters 3 in the first light shielding portion 41 are separated by the optical adhesive layer 8, there may be a case where part of large-angle light emitted by the first light emitting unit 201, such as light L16R, light L16B, and light L16G in FIG. 14, avoids the color filter 3 located lower in the first light shielding portion 41 and is directed from the optical adhesive layer 8 to an upper-layer color filter 3.

In the embodiments of the present disclosure, the blue color filter B is arranged on a side of the red color filter R away from the substrate 1, so that even if the large-angle light L16 leaks out from the optical adhesive layer 8, it can be ensured that the intensity of the leaked light is relatively low. For example, for the red light emitting unit 21R and the green light emitting unit 23G, red large-angle light L16R and green large-angle light L16G respectively emitted thereby are blocked after passing through the blue color filter B and cannot be emitted out. For the blue light emitting unit 22B, since the brightness proportion of the blue light in white light synthesized by using the three primary colors of red, green and blue is the lowest among the three primary colors, after blue large-angle light L16B is incident to the blue color filter B in the first light shielding portion 41 through the optical adhesive layer 8, the light intensity of the blue large-angle light L16B is the weakest among the three primary colors of red, green and blue, which can therefore also meet the low-brightness privacy requirement at a large viewing angle. In addition, by adopting such a configuration, the width of the color filter 3 in the first light shielding portion 41 may be configured to be relatively small, which may avoid affecting the small-angle light exiting of the first light emitting unit 201.

In an embodiment, as shown in FIG. 15, which is a sectional schematic diagram of another display panel according to an embodiment of the present disclosure, the display panel includes a privacy region A1 and a sharing region A2. The privacy region A1 includes a first light emitting unit 201 and a first light shielding portion 41. The sharing region A2 includes a second light emitting unit 202. The light shielding layer 4 further includes a second light shielding portion 42. At least part of the second light shielding portion 42 is located in the sharing region A2. The second light shielding portion 42 surrounds the second opening K2. In the direction h1 perpendicular to the plane of the substrate 1, the second light shielding portion 42 at least partially does not overlap with the second light emitting unit 202; at least part of the second light shielding portion 42 is located in the sharing region A2. The second light shielding portion 42 includes at least two color filters 3 that are stacked. In the direction h1 perpendicular to the plane of the substrate 1, an optical adhesive layer 8 is provided between two adjacent color filters 3 in the first light shielding portion 41. Two adjacent color filters 3 in the second light shielding portion 42 are in contact with each other. FIG. 15 schematically illustrates that the second light shielding portion 42 includes the first-color filter 31, the second-color filter 32, and the third-color filter 33.

The smaller the distance between the light shielding portion and the pixel definition layer in the direction h1 perpendicular to the plane of the substrate 1, the more conducive it is to emission of large-angle light. Therefore, by adopting such a configuration, the distance H11 between the surface of the uppermost color filter 3 in the first light shielding portion 41 and the pixel definition layer 5 in the direction h1 perpendicular to the plane of the substrate 1 can be greater than the distance H12 between the surface of the uppermost color filter 3 in the second light shielding portion 42 and the pixel definition layer 5 in the direction h1 perpendicular to the plane of the substrate 1, so that the light-exiting angle of the second light emitting unit 202 can be increased, and the light-exiting angle of the first light emitting unit 201 can be reduced, which is conducive to increasing the viewing angle of the display panel in the sharing mode and reducing the viewing angle of the display panel in the privacy mode.

Exemplarily, as shown in FIG. 15, in addition to the first part 301 and the second part 302, the color filters 3 of each color, such as the first-color filter 31, the second-color filter 32 and the third-color filter 33, may further include a third part 303. The third parts 303 of color filters 3 of different colors may at least partially overlap in the directionh1 perpendicular to the plane of the substrate 1, so as to form the above-mentioned second light shielding portion 42.

FIG. 15 only illustrates the first light emitting unit 201 of the first-color light emitting unit 21 and the second light emitting unit 202 of the first-color light emitting unit 21 as an example.

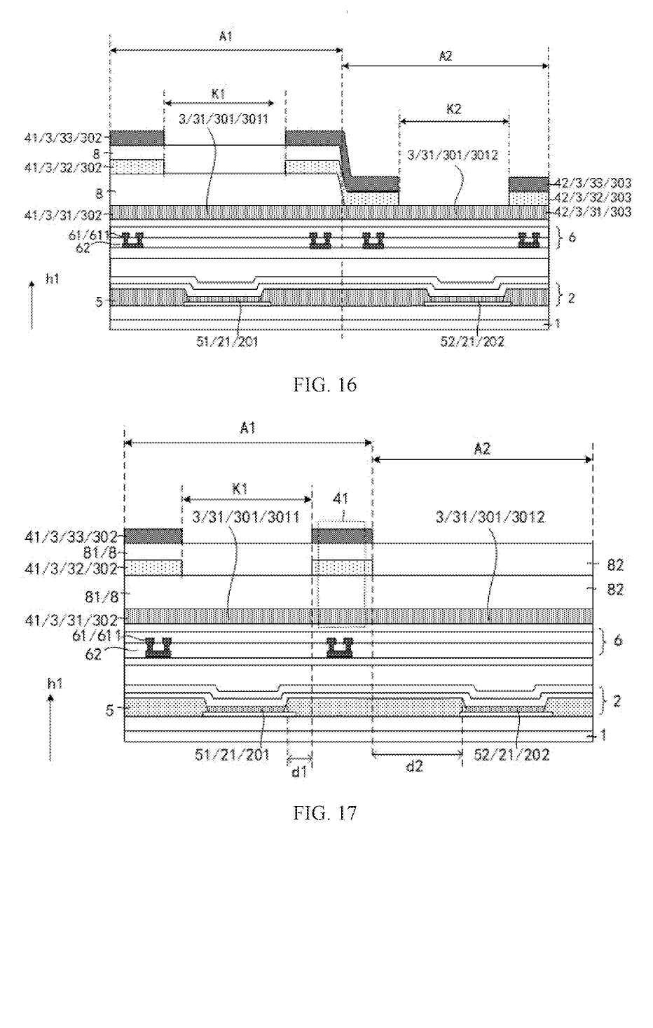

It should be noted that the color filters 3 in the second light shielding portion 42 and the color filters 3 in the first light shielding portion 41 illustrated in FIG. 15 are disconnected in a boundary region between the sharing region A2 and the privacy region A1 merely for illustration. In another optional implementation, as shown in FIG. 16, FIG. 16 is a sectional schematic diagram of another display panel according to an embodiment of the present disclosure, an acute included angle may be formed between the side surface and the bottom surface of the optical adhesive layer 8. That is, the side surface of the optical adhesive layer 8 may be obliquely arranged relative to the plane of the substrate 1, and the second-color filter 32 and the third-color filter 33 may each cover the side surface of the optical adhesive layer 8 located therebelow. By adopting such a configuration, the color filters 3 in the second light shielding portion 42 and the color filters 3 in the first light shielding portion 41 may be connected in the boundary region between the sharing region A2 and the privacy region A1.

As shown in FIG. 16, the second-color filter 32 and the third-color filter 33 may each include a portion in contact with the optical adhesive layer 8 and a portion not in contact with the optical adhesive layer 8. The portion in contact with the optical adhesive layer 8 belongs to the first light shielding portion 41, and the portion not in contact with the optical adhesive layer 8 belongs to the second light shielding portion 42.

Exemplarily, as shown in FIG. 17, which is a sectional schematic diagram of another display panel according to an embodiment of the present disclosure, the display panel includes a privacy region A1 and a sharing region A2. The privacy region A1 includes a first light emitting unit 201 and a first light shielding portion 41. The sharing region A2 includes a second light emitting unit 202. The optical adhesive layer 8 includes a first optical adhesive layer 81, and at least part of the first optical adhesive layer 81 is located between two adjacent color filters 3 in the first light shielding portion 41.

As shown in FIG. 17, the display panel further includes a second optical adhesive layer 82 located in the sharing region A2. The thickness of the second optical adhesive layer 82 is equal to the thickness of the first optical adhesive layer 81. By adopting such a configuration, the second optical adhesive layer 82 can be used to level off the film layer thickness step difference caused by absence of the light shielding portion in the sharing region A2, which is beneficial to improving the reliability of the display panel.

FIG. 17 schematically illustrates that the privacy region A1 includes two first optical adhesive layers 81, and the sharing region A2 includes two second optical adhesive layers 82. In an embodiment, as shown in FIG. 17, two first optical adhesive layers 81 and the two second optical adhesive layers 82 may be connected in a one-to-one correspondence, and the two connected to each other may form an integral structure, that is, no interface may be included between the two connected to each other.

It should be noted that, for the first light emitting unit 201 and the second light emitting unit 202 that are arranged adjacent to each other, taking the orientation shown in FIG. 17 as an example, the first light shielding portion 41 located on the right side of the first light emitting unit 201 is located on the left side of the second light emitting unit 202. In the embodiments of the present disclosure, the shortest distance d1 between the first light shielding portion 41 and the first pixel opening 51 may be configured to be less than the shortest distance d2 between the first light shielding portion 41 and the second pixel opening 52, so that the first light shielding portion 41 receives more emitted light of the first light emitting unit 201 and receives less emitted light of the second light emitting unit 202.

Exemplarily, as shown in FIG. 12, FIG. 13, FIG. 14, FIG. 15, FIG. 16, and FIG. 17, the light shielding layer 4 includes three color filters 3 that are stacked and have colors different from one another. FIG. 12, FIG. 13, FIG. 14, FIG. 15, FIG. 16, and FIG. 17 each schematically illustrate that the three color filters 3 respectively include the first-color filter 31, the second-color filter 32, and the third-color filter 33.

As shown in FIG. 12, FIG. 13, FIG. 14, FIG. 15, FIG. 16 and FIG. 17, the display panel further includes a touch layer 6 located between the light shielding layer 4 and the light emitting unit layer 2. The touch layer 6 includes at least one touch metal layer 61 and at least one touch insulating layer 62, and the touch metal layer 61 includes a touch metal trace 611. Along the direction h1 perpendicular to the plane of the substrate 1, the touch metal trace 611 at least partially overlaps with each of the three color filters 3 in the first light shielding layer 401. The position where the three color filters 3 overlap has good light shielding performance. In the embodiments of the present disclosure, by making the touch metal trace 611 at least partially overlap with each of the three color filters 3 in the first light shielding layer 401, the visibility of the touch metal trace 61 can be reduced, and the display effect of the display panel can be improved.

In an embodiment, along a direction away from the substrate 1, refractive indexes of at least two color filters 3 in the light shielding layer 4 gradually increase. As shown in FIG. 11, the first light shielding portion 41 includes at least the first-color filter 31 and the second-color filter 32 that are stacked. The second-color filter 32 is located on a side of the first-color filter 31 away from the substrate 1. The refractive index of the second-color filter 32 is greater than the refractive index of the first-color filter 31.

By adopting such a configuration, as shown in FIG. 11, for the large-angle light emitted by the first light emitting unit 201 of the second-color light emitting unit 22, such as light L14 shown in FIG. 11, the light L14 may be incident to the first side surface S311 of the first-color filter 31 in the first light shielding portion 41 corresponding thereto, and the first side surface S311 is covered by the second-color filter 32 corresponding to the second-color light emitting unit 22. In the embodiments of the present disclosure, by making the refractive index of the second-color filter 32 greater than the refractive index of the first-color filter 31, light incident on the first side surface S311 may be totally reflected at the side wall S31. Compared with the incident light, the light-exiting angle of the reflected light may become smaller, which is beneficial to reducing the viewing angle in the privacy mode and improving the privacy effect in the privacy mode.

Exemplarily, as shown in FIG. 11, the display panel further includes an optical adhesive layer 8 covering the light shielding layer 4. The refractive index of the optical adhesive layer 8 is greater than the refractive index of the color filter 3, for example, the refractive index of the optical adhesive layer 8 is greater than the refractive index of the second-color filter 32. The refractive index of the second-color filter 32 is greater than the refractive index of the first-color filter 31.

By adopting such a configuration, as shown in FIG. 11, for the large-angle light emitted by the first light emitting unit 201, such as light L15 shown in FIG. 11, the light L15 may be incident to the interface between the second-color filter 32 in the first light shielding portion 41 and the optical adhesive layer 8, that is, a second side surface S321 of the second-color filter 32 in the first light shielding portion 41, and the second side surface S321 is covered by the optical adhesive layer 8. In the embodiments of the present disclosure, by making the refractive index of the optical adhesive layer 8 greater than the refractive index of the second-color filter 32, light incident to the second side surface S321 of the second-color filter 32 may be totally reflected at the second side surface S321. Compared with the incident light, the light-exiting angle of the reflected light may become smaller, which is beneficial to reducing the viewing angle in the privacy mode and improving the privacy effect in the privacy mode.

In the embodiments of the present disclosure, an operation mode of the display panel includes a privacy mode, and in the privacy mode, the maximum viewing angle of the display panel is θ1. The color filter 3 includes a side surface and a bottom surface, and an included angle, on a side away from the first opening, between the side surface and the bottom surface is α, where α > 90°-θ1. Taking the first-color filter 31 in FIG. 11 as an example, the first-color filter 31 includes a first side surface S311 and a first bottom surface S312, and an included angle between the first side surface S311 and the first bottom surface S312 is α1. The included angle may be understood as an included angle α1, on a side away from the first opening K1 corresponding to the second-color light emitting unit 22, between the first side surface S311 and the first bottom surface S312, where 90° > α1 > 90° - θ1. By adopting such a configuration, after the large-angle light emitted by the first light emitting unit 201 in the second-color light emitting units 22, such as light L14 shown in FIG. 11, is reflected by the first side surface S311, the light-exiting angle of the reflected light can be less than θ1, which is beneficial to narrowing the viewing angle in the privacy mode and ensuring the privacy effect.

Taking the second-color filter 32 in FIG. 11 as an example, the second-color filter 32 includes a second side surface S321 and a second bottom surface S322. An included angle, on a side away from the first opening K1 corresponding to the first-color light emitting unit 21, between the second side surface S321 and the second bottom surface S322 is α2, where 90° > α2 > 90° - θ1. By adopting such a configuration, after the large-angle light emitted by the first light emitting unit 201 in the first-color light emitting units 21, such as light L15 shown in FIG. 11, is reflected by the second side surface S321, the light-exiting angle of the light reflected by the second side surface S321 can be less than θ1, which is beneficial to narrowing the viewing angle in the privacy mode and ensuring the privacy effect.

Exemplarily, as shown in FIG. 18, FIG. 18 is a top-view schematic diagram of another display panel according to an embodiment of the present disclosure, in addition to the first-color light emitting units 21, the light emitting unit layer further includes second-color light emitting units 22, and the second-color light emitting units 22 and the first-color light emitting units 21 have different colors. The second-color light emitting units 22 at least include a first light emitting unit 201 and a second light emitting unit 202. The display panel includes first groups G1 and second groups G2. The first group G1 at least includes a first light emitting unit 201 in the first-color light emitting units 21 and a first light emitting unit 201 in the second-color light emitting units 22. The second group G2 at least includes a second light emitting unit 202 in the first-color light emitting units 21 and a second light emitting unit 202 in the second-color light emitting units 22. The first groups G1 and the second groups G2 are alternately and repeatedly arranged along the first direction h21 and along the second directionh22. By adopting such a configuration, it can be ensured that the privacy pixels and the sharing pixels both have a relatively large area, which is beneficial to ensuring the display brightness of the display panel.

In an embodiment, as shown in FIG. 18, in the first group G1, the first light emitting unit 201 in the first-color light emitting units 21 and the first light emitting unit 201 in the second-color light emitting units 22 are arranged along the fourth direction h24. In the second group G2, the second light emitting unit 202 in the first-color light emitting units 21 and the second light emitting unit 202 in the second-color light emitting units 22 are arranged along the fourth directionh24. The first direction h21, the second directionh22 and the fourth direction h24 intersect with each other, and the first direction h21, the second direction h22 and the fourth directionh24 are all parallel to the plane of the substrate 1.

Exemplarily, as shown in FIG. 18, the light emitting unit layer further includes third-color light emitting units 23. The third-color light emitting units 23 include a first light emitting unit 201 and a second light emitting unit 202. In addition, the light-exiting color of the first light emitting unit 201 and the second light emitting unit 202 in the first-color light emitting units 21, the light-exiting color of the first light emitting unit 201 and the second light emitting unit 202 in the second-color light emitting units 22, and the light-exiting color of the first light emitting unit 201 and the second light emitting unit 202 in the third-color light emitting units 23 are different from one another.

Being different from one another includes: the light-exiting color of the first light emitting unit 201 in the first-color light emitting units 21 being different from the light-exiting color of the first light emitting unit 201 in the second-color light emitting units 22; the light-exiting color of the first light emitting unit 201 in the first-color light emitting units 21 being different from the light-exiting color of the first light emitting unit 201 in the third-color light emitting units 23; the light-exiting color of the first light emitting unit 201 in the second-color light emitting units 22 being different from the light-exiting color of the first light emitting unit 201 in the third-color light emitting units 23; the light-exiting color of the second light emitting unit 202 in the first-color light emitting units 21 being different from the light-exiting color of the second light emitting unit 202 in the second-color light emitting units 22; the light-exiting color of the second light emitting unit 202 in the first-color light emitting units 21 being different from the light-exiting color of the second light emitting unit 202 in the third-color light emitting units 23; and the light-exiting color of the second light emitting unit 202 in the second-color light emitting units 22 being different from the light-exiting color of the second light emitting unit 202 in the third-color light emitting units 23.

The first light emitting unit and the second light emitting unit in the same-color light emitting unit have the same color, that is, the light-exiting color of the first light emitting unit 201 in the first-color light emitting units 21 is the same as the light-exiting color of the second light emitting unit 202 in the first-color light emitting units 21. The light-exiting color of the first light emitting unit 201 in the second-color light emitting units 22 is the same as the light-exiting color of the second light emitting unit 202 in the second-color light emitting units 22. The light-exiting color of the first light emitting unit 201 in the third-color light emitting units 23 is the same as the light-exiting color of the second light emitting unit 202 in the third-color light emitting units 23.

In an embodiment, as shown in FIG. 18, the first group G1 includes the first light emitting units 201 of two third-color light emitting units 23, and the second group G2 includes the second light emitting units 202 of two third-color light emitting units 23.

In the first group G1, the first light emitting units 201 of two third-color light emitting units 23 are arranged along the third direction h23, the first light emitting unit 201 of one of the two third-color light emitting units 23 and the first light emitting unit 201 of the first-color light emitting unit 21 are arranged along the first direction h21, and the first light emitting unit 201 of the other one of the two third-color light emitting units 23 and the first light emitting unit 201 of the first-color light emitting unit 21 are arranged along the second direction h22.

In the second group G2, the second light emitting units 202 of two third-color light emitting units 23 are arranged along the third direction h23, the second light emitting unit 202 of one of the two third-color light emitting units 23 and the second light emitting unit 202 of the first-color light emitting unit 21 are arranged along the first direction h21, and the second light emitting unit 202 of the other one of the two third-color light emitting units 23 and the second light emitting unit 202 of the first-color light emitting unit 21 are arranged along the second direction h22.

Exemplarily, as shown in FIG. 18, the light shielding layer 4 may not be arranged above each second light emitting unit 202 in the second group G2, and the first light shielding portion 41 is arranged only above each first light emitting unit 201 in the first group G1.

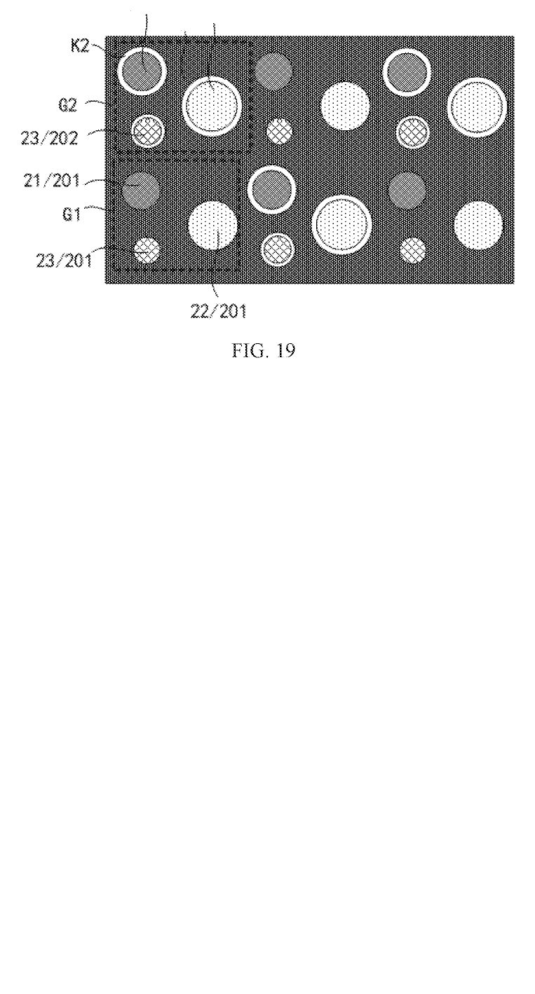

Alternatively, the light shielding layer 4 may also be arranged in the second group G2. As shown in FIG. 19, which is a top-view schematic diagram of another display panel according to an embodiment of the present disclosure, the light shielding layer 4 includes a second light shielding portion 42 and a second opening K2. The second light shielding portion 42 surrounds the second opening K2. The area of the orthographic projection of the second opening K2 on the plane of the substrate may be greater than the area of the second light emitting unit 202.

In an embodiment of the present disclosure, in the first-color light emitting unit 21, the width of the first light emitting unit 201 is greater than or equal to the width of the second light emitting unit 202 in the same direction. In the second-color light emitting unit 22, the width of the first light emitting unit 201 is greater than or equal to the width of the second light emitting unit 202 in the same direction. The width direction of the first light emitting unit 201 is parallel to the width direction of the second light emitting unit 202, for example, the width direction may be parallel to the first direction h21 or the second directionh22.

FIG. 18 and FIG. 19 schematically illustrate that, in the first-color light emitting unit 21, the width of the first light emitting unit 201 is equal to the width of the second light emitting unit 202 in the same direction, and in the second-color light emitting unit 22, the width of the first light emitting unit 201 is equal to the width of the second light emitting unit 202 in the same direction.

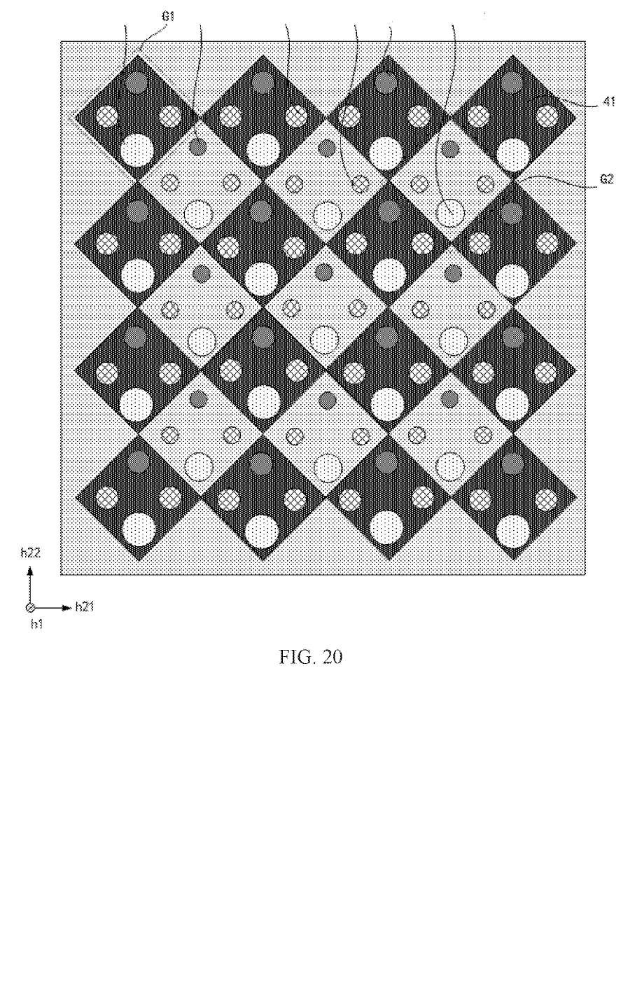

Alternatively, as shown in FIG. 20, FIG. 20 is a top-view schematic diagram of another display panel according to an embodiment of the present disclosure, in the first-color light emitting unit 21, the width of the first light emitting unit 201 is greater than the width of the second light emitting unit 202 in the same direction; in the second-color light emitting unit 22, the width of the first light emitting unit 201 is greater than the width of the second light emitting unit 202 in the same direction.

Exemplarily, in the embodiments of the present disclosure, the first light emitting unit 201 may also be lit in the sharing mode, so as to increase the brightness in the sharing mode. In the embodiments of the present disclosure, by making the width of the first light emitting unit 201 greater than or equal to the width of the second light emitting unit 202 in the same direction, the brightness decay that may occur in the first light emitting unit 201 due to long-time lighting can be compensated.

It should be noted that the width of the light emitting unit may be understood as the width of the pixel opening corresponding to the light emitting unit in the same direction. The width of the first light emitting unit 201 is greater than or equal to the width of the second light emitting unit 202 in the same direction, that is, the width of the first pixel opening 51 corresponding to the first light emitting unit 201 is greater than or equal to the width of the second pixel opening 52 corresponding to the second light emitting unit 202.

In addition, the shapes of the light emitting units in FIG. 18, FIG. 19, and FIG. 20 are illustrated as circular merely for illustration. The embodiments of the present disclosure may also adjust the shapes of the light emitting units according to different display requirements, which is not limited in the embodiments of the present disclosure.

Exemplarily, as shown in FIG. 18, the display panel further includes scan lines SL and data lines DL. The scan lines SL extend along the third direction h23, and the scan lines SL are arranged along the fourth direction h24. The data lines DL extend along the fourth direction h24, and the data lines DL are arranged along the third direction h23. The third direction h23 and the fourth directionh24 are both parallel to a plane defined by the intersection of the first direction h21 and the second direction h22. In addition, the third direction h23 respectively intersects with the first direction h21 and the second directionh22, and the fourth direction h24 respectively intersects with the first direction h21 and the second directionh22. FIG. 18 schematically illustrates that the third direction h23 is perpendicular to the fourth direction h24.

When the display panel is in operation, the data lines DL provide data voltages, and the scan lines SL sequentially provide control signals for controlling sub-pixels to which the light emitting units belong to start charging, so that the corresponding sub-pixels are charged with the data voltages provided by the data lines DL, and the light emitting units are controlled to be lit with required brightness.

In an embodiment, the first-color light emitting unit 21 is a red light emitting unit, and the first-color filter 31 is a red color filter.

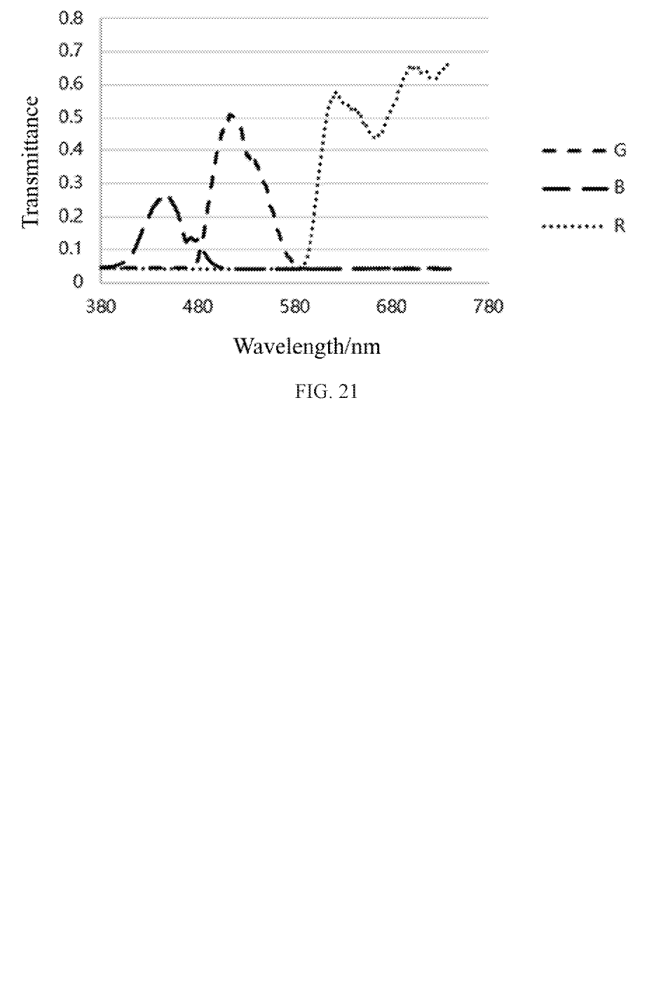

As shown in FIG. 21, FIG. 21 is a spectral schematic diagram of a red color filter R, a blue color filter B, and a green color filter G according to an embodiment of the present disclosure, it can be seen from FIG. 21 that the red color filter R has relatively low transmittance in its visible light waveband. In the embodiments of the present disclosure, the red color filter R is selected to form the first light shielding portion 41, so as to ensure the light shielding performance of the first light shielding portion 41, and to reduce the total thickness of the first light shielding portion 41 including the red color filter R, which is beneficial to realizing the thinning and lightening of the display panel.

Exemplarily, the second-color filter 32 is a blue color filter. It can be seen from FIG. 21 that the transmission wavebands of the red color filter R and the blue color filter B are almost completely staggered. In the embodiments of the present disclosure, the first light shielding portion 41 is formed by selecting the red color filter R and the blue color filter B, which can ensure that the first light shielding portion 41 has relatively good light shielding capability.

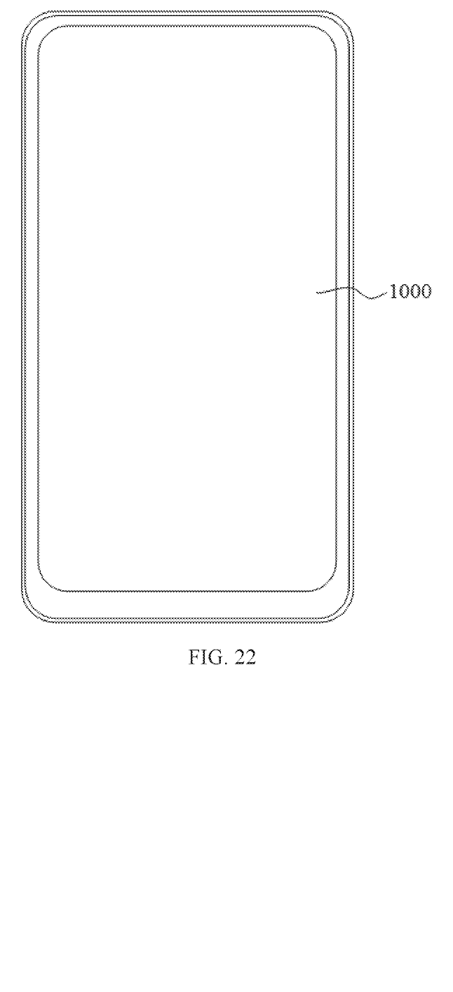

Based on the same inventive concept, an embodiment of the present disclosure further provides a display device. As shown in FIG. 22, which is a schematic diagram of a display device according to an embodiment of the present disclosure, the display device includes the display panel 1000 described above. The specific structure of the display panel 1000 has been described in detail in the above embodiments, and details are not described herein again. It is understandable that, the display device shown in FIG. 22 is merely illustrative, and the display device can be any electronic device having a display function such as a mobile phone, a tablet computer, a notebook computer, an electronic paper book, a vehicle-mounted display screen, or a television.

The above description merely illustrates some preferred embodiments of the present disclosure and is not intended to limit the present disclosure, and any modification, equivalent substitution, improvement and the like made within a spirit and a principle of the present disclosure shall fall with the scope of the present disclosure.

It should be noted that, the above-described embodiments are merely for illustrating the present disclosure but not intended to provide any limitation. Although the present disclosure has been described in detail with reference to the above-described embodiments, it should be understood that those skilled in the art may also modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, comprising:
a substrate;
a light emitting unit layer located on a side of the substrate, wherein the light emitting unit layer comprises first-color light emitting units, and the first-color light emitting units comprise at least a first light emitting unit and a second light emitting unit;
color filters comprising first-color filters and second-color filters, wherein a color of the first-color filters is different from a color of the second-color filters, the first-color filters are located on a light-exiting side of the first-color light emitting units; and in a direction perpendicular to a plane of the substrate, the first-color filters at least partially overlap with the first-color light emitting units; and
a light shielding layer located on a light-exiting side of the light emitting unit layer, wherein the light shielding layer comprises a first light shielding portion, a first opening and a second opening, the first light shielding portion surrounds the first opening; and, along the direction perpendicular to the plane of the substrate, the first light shielding portion at least partially does not overlap with the first light emitting unit, the first opening at least partially overlaps with the first light emitting unit, and the second opening at least partially overlaps with the second light emitting unit,
wherein the first light shielding portion comprises a first-color filter and a second-color filter that are stacked.

2. The display panel according to claim 1, wherein
the light shielding layer comprises a first light shielding layer and a second light shielding layer that is located on a side of the first light shielding layer away from the substrate;
the first light shielding layer comprises a first sub-opening and a second sub-opening, and the second light shielding layer comprises a third sub-opening and a fourth sub-opening; and along the direction perpendicular to the plane of the substrate, the first sub-opening and the third sub-opening at least partially overlap with the first light emitting unit, and the second sub-opening and the fourth sub-opening at least partially overlap with the second light emitting unit; and
the first opening comprises the first sub-opening and the third sub-opening; and the second opening comprises the second sub-opening and the fourth sub-opening.

3. The display panel according to claim 2, further comprising a pixel definition layer, wherein
the pixel definition layer comprises a first pixel opening and a second pixel opening, at least part of the first light emitting unit is located in the first pixel opening, and at least part of the second light emitting unit is located in the second pixel opening;
along a first direction, a shortest distance between an edge of the first pixel opening and an edge of the first sub-opening is d11, and a shortest distance between the edge of the first pixel opening and an edge of the third sub-opening is d21, where d11 > d21; and the first direction is parallel to the plane of the substrate; and
along the first direction, a shortest distance between an edge of the second pixel opening and an edge of the second sub-opening is d12, and a shortest distance between the edge of the second pixel opening and an edge of the fourth sub-opening is d22, where d22 > d12.

4. The display panel according to claim 3, wherein
along the first direction, a width of the first sub-opening is W11, a width of the third sub-opening is W21, a width of the first pixel opening is W01, a width of the second sub-opening is W12, a width of the fourth sub-opening is W22, and a width of the second pixel opening is W02, and
W11 ≥ W21 ≥ W01; and W22 > W12 ≥ W02.

5. The display panel according to claim 4, wherein
W11 - W21 ≤ 3 μm.

6. The display panel according to claim 4, wherein
W12 - W02 > 10 μm.

7. The display panel according to claim 2, wherein
the first light shielding layer comprises the first-color filter and the second-color filter that are stacked, and the second light shielding layer comprises a black matrix; or the first light shielding layer comprises the black matrix, and the second light shielding layer comprises the first-color filter and the second-color filter that are stacked.

8. The display panel according to claim 7, further comprising a touch layer, wherein the touch layer comprises a touch metal trace, and along the direction perpendicular to the plane of the substrate, the touch metal trace at least partially overlaps with the black matrix.

9. The display panel according to claim 1, wherein
a thickness of the first-color filter at least partially overlapping with a first-color light emitting unit is less than or equal to a thickness of the first-color filter in the first light shielding portion.

10. The display panel according to claim 9, further comprising a transparent cushion layer, wherein along the direction perpendicular to the plane of the substrate, the transparent cushion layer at least partially overlaps with the first-color light emitting unit and is located on a side of the first-color filter close to the substrate.

11. The display panel according to claim 1, wherein
the light emitting unit layer further comprises second-color light emitting units and third-color light emitting units, the second-color light emitting units comprise the first light emitting unit and the second light emitting unit; the third-color light emitting units comprise the first light emitting unit and the second light emitting unit; and a light-exiting color of the first light emitting unit and the second light emitting unit in the first-color light emitting units, a light-exiting color of the first light emitting unit and the second light emitting unit in the second-color light emitting units, and a light-exiting color of the first light emitting unit and the second light emitting unit in the third-color light emitting units are different from one another;
along a first direction, the first-color light emitting units, the second-color light emitting units and the third-color light emitting units are arranged alternately in sequence;
along a second direction, the first-color light emitting units, the second-color light emitting units and the third-color light emitting units are arranged alternately in sequence;
along a third direction, the first-color light emitting units, the second-color light emitting units and the third-color light emitting units are arranged alternately in sequence; and
the first direction, the second direction and the third direction are all parallel to the plane of the substrate, and any two of the first direction, the second direction, and the third direction intersect with each other.

12. The display panel according to claim 11, wherein
in the first-color light emitting units, a width of the first light emitting unit is smaller than a width of the second light emitting unit in a same direction;
in the second-color light emitting units, a width of the first light emitting unit is smaller than a width of the second light emitting unit in the same direction; and
in the third-color light emitting units, a width of the first light emitting unit is smaller than a width of the second light emitting unit in the same direction.

13. The display panel according to claim 7, wherein
in the direction perpendicular to the plane of the substrate, two adjacent color filters in the first light shielding portion are in contact with each other.

14. The display panel according to claim 13, wherein
the first light shielding portion further comprises a third-color filter; the first-color filter, the second-color filter and the third-color filter are stacked; and a color of the first-color filter, a color of the second-color filter, and a color of the third-color filter are different from one another.

15. The display panel according to claim 1, wherein
in the direction perpendicular to the plane of the substrate, an optical adhesive layer is provided between at least two adjacent ones of the color filters in the first light shielding portion.

16. The display panel according to claim 15, wherein a first-color light emitting unit comprises a red light emitting unit, and the first-color filter comprises a red color filter;
the light emitting unit layer further comprises a blue light emitting unit, the blue light emitting unit comprises the first light emitting unit and the second light emitting unit, and the second-color filter comprises a blue color filter; and
along the direction perpendicular to the plane of the substrate, a distance between the blue color filter and the substrate is greater than a distance between the red color filter and the substrate.

17. The display panel according to claim 15, further comprising: a privacy region and a sharing region, wherein
the privacy region comprises the first light emitting unit and the first light shielding portion, and the sharing region comprises the second light emitting unit,
the light shielding layer further comprises a second light shielding portion surrounding the second opening, and along the direction perpendicular to the plane of the substrate, the second light shielding portion at least partially does not overlap with the second light emitting unit; and at least part of the second light shielding portion is located in the sharing region, and
the second light shielding portion comprises at least two color filters that are stacked, and in the direction perpendicular to the plane of the substrate, two adjacent color filters in the second light shielding portion are in contact with each other.

18. The display panel according to claim 15, further comprising: a privacy region and a sharing region, wherein
the privacy region comprises the first light emitting unit and the first light shielding portion, and the sharing region comprises the second light emitting unit,
a first optical adhesive layer is formed between two adjacent color filters in the first light shielding portion, and
the sharing region further comprises a second optical adhesive layer, and a thickness of the second optical adhesive layer is the same as a thickness of the first optical adhesive layer.

19. The display panel according to claim 15, wherein
the light shielding layer comprises three color filters that are stacked and have colors different from one another; and
the display panel further comprises a touch layer comprising a touch metal trace, and along a direction perpendicular to a plane of the display panel, the touch metal trace at least partially overlaps with each of three color filters in the first light shielding layer.

20. The display panel according to claim 1, wherein
an operating mode of the display panel comprises a privacy mode, and in the privacy mode, a maximum viewing angle of the display panel is θ1; and
the color filter comprises a side surface and a bottom surface; and an included angle, on a side away from the first opening, between the side surface and the bottom surface is α, where α > 90° - θ1.

21. The display panel according to claim 1, wherein the light emitting unit layer further comprises second-color light emitting units, a color of the second-color light emitting units is different from a color of the first-color light emitting units, and the second-color light emitting units at least comprise a first light emitting unit and a second light emitting unit;
the display panel comprises first groups and second groups, one first group of the first groups at least comprises the first light emitting unit in the first-color light emitting units and the first light emitting unit in the second-color light emitting units; and one second group of the second groups at least comprises the second light emitting unit in the first-color light emitting units and the second light emitting unit in the second-color light emitting units; and
the first groups and the second groups are alternately and repeatedly arranged along a first direction and along a second direction.

22. The display panel according to claim 21, wherein
in the first-color light emitting units, a width of the first light emitting unit is greater than or equal to a width of the second light emitting unit in a same direction; and
in the second-color light emitting units, a width of the first light emitting unit is greater than or equal to a width of the second light emitting unit in a same direction.

23. The display panel according to claim 1, wherein
the first-color light emitting units are red light emitting units, and the first-color filters are red color filters.

24. The display panel according to claim 1, wherein
the second-color filters are blue color filters.

25. The display panel according to claim 1, wherein
an operating mode of the display panel comprises a privacy mode and a sharing mode,
in the privacy mode, the first light emitting unit emits light; and
in the sharing mode, the second light emitting unit emits light.

26. A display device, comprising a display panel, wherein the display panel comprises:
a substrate;
a light emitting unit layer located on a side of the substrate, wherein the light emitting unit layer comprises first-color light emitting units, and the first-color light emitting units comprise at least a first light emitting unit and a second light emitting unit;
color filters comprising first-color filters and second-color filters, wherein a color of the first-color filters is different from a color of the second-color filters, the first-color filters are located on a light-exiting side of the first-color light emitting units; and in a direction perpendicular to a plane of the substrate, the first-color filters at least partially overlap with the first-color light emitting units; and
a light shielding layer located on a light-exiting side of the light emitting unit layer, wherein the light shielding layer comprises a first light shielding portion, a first opening and a second opening, the first light shielding portion surrounds the first opening; and along the direction perpendicular to the plane of the substrate, the first light shielding portion at least partially does not overlap with the first light emitting unit, the first opening at least partially overlaps with the first light emitting unit, and the second opening at least partially overlaps with the second light emitting unit,
wherein the first light shielding portion comprises a first-color filter and a second-color filter that are stacked.
